(19) United States
(12) Patent Application Publication
(10) Pub. No.: US 2025/0239454 A1
(43) Pub. Date: Jul. 24, 2025

(54) SUBSTRATE TREATING METHOD AND SUBSTRATE TREATING SYSTEM

(71) Applicant: SCREEN Holdings Co., Ltd., Kyoto (JP)

(72) Inventors: Hiroaki ISHII, Kyoto (JP); Junichi ISHII, Kyoto (JP)

(21) Appl. No.: 18/705,457

(22) PCT Filed: Oct. 17, 2022
(86) PCT No.: PCT/JP2022/038617

§ 371 Date: Apr. 26, 2024

(30) Foreign Application Priority Data
Oct. 26, 2021 (JP) 2021-174625

(51) Int. Cl. H01L 21/306; G03F 7/00; G03F 7/16; H01L 21/311; H01L 21/66

(52) U.S. Cl. CPC H01L 21/30625; G03F 7/162; G03F 7/70991; H01L 21/31111; H01L 22/12

(57) ABSTRACT

This disclosure relates to a substrate treating method and a substrate treating system. The substrate treating method includes a rotating step of rotating a substrate in a horizontal posture by a holding rotator, a polishing step of performing polishing to a back face of the substrate in a chemo-mechanical grinding manner by contacting a polisher against the back face of the rotating substrate, the polisher having a resin body where abrasive grains are distributed, a heating step of heating the substrate while the polishing is performed, a resist coating step of coating a front face of the substrate, whose back face is subject to the polishing, with a resist, and an exposing step of exposing the resist with which the front face of the substrate is coated.

### TECHNICAL FIELD

The present invention relates to a substrate treating method and a substrate treating system for polishing treatment of a back face of a substrate. Examples of substrates include semiconductor substrates, substrates for flat panel displays (FPDs), glass substrates for photomasks, substrates for optical disks, substrates for magnetic disks, ceramic substrates, and substrates for solar cells. Examples of the FPDs include liquid crystal display devices and organic electroluminescence (EL) display devices. Here, the back face of the substrate is a face where no electronic circuits are formed, which is opposite to a front face of the substrate as a face (device face) where electronic circuits are formed.

### BACKGROUND ART

A polishing device for polishing the back face of the substrate includes a holding rotator and a polishing head. The holding rotator rotates the substrate while holding the substrate in a horizontal posture. The polishing device supplies a polishing solution, and further causes the polishing head to contact against the back face of the rotating substrate for polishing the substrate (see, for example, Patent Literature 1).

Another type of polishing devices is a grinding device that performs dry-type chemo-mechanical grinding (CMG) to a substrate (see, for example, Patent Literature 2). The grinding device includes a holding rotator and a synthetic grindstone. The synthetic grindstone is formed by fixing a polishing agent (abrasive grain) with a resin binder. The grinding device grinds a substrate by contacting the synthetic grindstone against the substrate. Also, there is a substrate treating apparatus provided with a polisher for removing contaminants or contact marks on a back face of a substrate (see, for example, Patent Literature 3).

Patent Literature 4 discloses a grinding device provided with a grinding head. The grinding head includes a head body and an annular ring-shape grindstone. The annular ring-shape grindstone is located on a lower face of the head body. The lower face of the head body has a recess formed therein so as to correspond to a hollow portion at the center of the annular ring-shape grindstone. A suction hole communicating with a suction flow path is provided in an inner face of the recess.

### PRIOR ART DOCUMENT

### Patent Literature

### [Patent Literature 1]

Japanese Patent Publication No. 6162417

### [Patent Literature 2]

Japanese Patent Publication No. 6779540

### [Patent Literature 3]

Japanese Patent Publication No. 6740065

### [Patent Literature 4]

Japanese Unexamined Patent Publication No. 2021-053738

### SUMMARY OF INVENTION

### Technical Problem

The currently-used device having such a configuration has the following drawback. That is, the drawback is defocus (so-called out of focus) by an extreme ultraviolet (EUV) exposure device due to a substrate flatness of a back face of the substrate (e.g., wafer) in recent years. One cause of poor flatness is considered a scratch. As a result, in order to scrape off the scratch, it has been studied to adopt the synthetic grindstone as a polisher in Patent Literature 2. Here, it takes a long time to perform polishing treatment, and there is a desire to shorten time for the polishing treatment.

The present invention has been made regarding the state of the art noted above, and its object is to provide a substrate treating method and a substrate treating system that can shorten time for polishing treatment.

### Solution to Problem

The present invention is constituted as stated below to achieve the above object. One aspect of the present invention provides a substrate treating method including a rotating step of rotating a substrate in a horizontal posture by a holding rotator, a polishing step of performing polishing to a back face of the substrate in a chemo-mechanical grinding manner by contacting a polisher against the back face of the rotating substrate, the polisher having a resin body where abrasive grains are distributed, a heating step of heating the substrate while the polishing is performed, a resist coating step of coating a front face of the substrate, whose back face is subject to the polishing, with a resist, and an exposing step of exposing the resist with which the front face of the substrate is coated.

The substrate treating method of the present invention includes the rotating step, the polishing step, the heating step, and the resist coating step. The polisher has a resin body in which abrasive grains are distributed. The polisher polishes the back face of the substrate in the chemo-mechanical grinding manner by contacting against the back face of the rotating substrate. The substrate is heated when the polishing is performed. When the substrate is heated, a polishing rate can increase. This can shorten time for polishing treatment. Moreover, the front face of the substrate is coated with the resist, and the polishing is performed to the back face of the substrate. This achieves sufficient flatness of the substrate coated with the resist, whereby the defocus drawback of the exposure device can be overcome.

Moreover, another aspect of the present invention provides a substrate treating method including a resist coating step of coating a front face of a substrate with a resist, a rotating step of rotating the substrate, coated with the resist, in a horizontal posture by a holding rotator, a polishing step of performing polishing to a back face of the rotating substrate in a chemo-mechanical grinding manner by contacting a polisher against the back face of the substrate, the polisher having a resin body where abrasive grains are distributed, a heating step of heating the substrate while the polishing is performed, and an exposing step of exposing the resist with which the front face of the substrate, whose back face is subject to the polishing, is coated.

Moreover, it is preferred that the substrate treating method described above further includes a controlling step of adjusting a polishing rate by controlling a heating temperature of the substrate in the heating step. Raising and lowering the heating temperature of the substrates allow increase and decrease of the polishing rate.

Moreover, it is preferred in the substrate treating method described above that, in the controlling step, the polishing rate is adjusted by controlling at least one selected from a contact pressure of the polisher against the substrate, a moving speed of the polisher, a rotation speed of the polisher, and a rotation speed of the substrate. For example, raising the heating temperature of the substrate while keeping the polishing rate allows decreased contact pressure of the polisher against the substrate. This can suppress load of the substrate caused by the contact pressure. That is, excess pushing against the substrate W can be prevented.

Moreover, in one example of the substrate treating method described above, the holding rotator includes a spin base that is rotatable around a rotary axis extending in an up-down direction, three or more holding pins that are provided on a top face of the spin base so as to surround the rotary axis in a ring shape and configured to hold the substrate by sandwiching a side face of the substrate so that the substrate is held apart from the top face of the spin base, and a first heater provided on the top face of the spin base, and the first heater heats the substrate in the heating step. The substrate can be heated with the first heater provided on the top face of the spin base.

Moreover, in another example of the substrate treating method described above, the holding rotator includes a spin base that is rotatable around a rotary axis extending in an up-down direction, three or more holding pins that are provided on a top face of the spin base so as to surround the rotary axis in a ring shape and configured to hold the substrate by sandwiching a side face of the substrate so that the substrate is held apart from the top face of the spin base, and a gas ejection port that is opened in the top face of the spin base and provided in a center portion of the spin base, and in the heating step, the gas ejection port heats the substrate by ejecting heated gas in such a manner that the gas flows in a gap between the substrate and the spin base from a portion adjacent to the center of the substrate to an outer periphery edge of the substrate.

Heated gas from the gas ejection port can heat the substrate. Moreover, a device face (front face) of the substrate faces the spin base. When gas is ejected from the gas ejection port, gas jets outward from the gap between the outer edge of the substrate and the spin base. Accordingly, the polishing scraps or a liquid, for example, can be prevented from adhering to the device face of the substrate. That is, the device face of the substrate can be protected.

Moreover, in another example of the substrate treating method described above, a second heater heats the polisher, thereby heating the substrate via the polisher in the heating step. When the polisher is heated, the substrate can be heated via the polisher. Moreover, an interface between the polisher and the back face of the substrate can be heated effectively.

Moreover, in another example of the substrate treating method described above, a heated water supply nozzle supplies heated water to the back face of the substrate, held by the holding rotator, thereby heating the substrate in the heating step. Heated water can heat the substrate W. Moreover, heated water can clean off the polishing scraps from the back face of the substrate.

Moreover, it is preferred that the substrate treating method described above further includes a dust particle suction step of jetting gas to dust particles, generated through the polishing by the polisher, from a jet port of the polishing head provided with the polisher and sucking the dust particles from a suction port of the polishing head. The gas is jetted from the jet port to the dust particles generated through the polishing by the polisher. Thereby, the dust particles attached to the face of the substrate are removed from the face of the substrate. The dust particles are sucked through the suction port. Consequently, the dust particles are hard to remain on the face of the substrate, achieving an enhanced removal rate of dust particles caused by the polishing.

Moreover, it is preferred that the substrate treating method described above further includes an etching step of supplying an etching solution to the back face of the rotating substrate to remove a film formed on the back face of the substrate prior to the polishing step. The polisher contacts against the back face of the rotating substrate to polish the back face of the substrate in the chemo-mechanical grinding manner. Here, it is found that, when a film is formed on the back face of the substrate, the polishing cannot be performed suitably due to the film. Then, the film formed on the back face of the substrate is removed by the etching step prior to the polishing step. This can perform the polishing treatment suitably.

Moreover, it is preferred that substrate treating method described above further includes an inspecting step of detecting a scratch formed on the back face of the substrate by an inspecting unit prior to the polishing step, and that the polishing step is performed when the inspecting unit detects the scratch. This can scrape the scratch detected by the inspecting unit, i.e., a selected scratch, in the polishing step.

Moreover, it is preferred in the substrate treating method described above that, in the inspecting step, the inspecting unit detects the scratch formed on the back face of the substrate and determines a depth of the scratch when the scratch is detected, that the polishing step is performed when the inspecting unit detects the scratch, and that, in the polishing step, the back face of the substrate is polished until a thickness corresponding to the depth of the scratch determined by the inspecting unit is scraped off. Accordingly, the depth of the scratch is recognized, achieving a suitable amount of polishing in a thickness direction of the substrate.

Another aspect of the present invention provides a substrate treating system including a coating device configured to coat a front face of a substrate with a resist, a polishing treatment device configured to polish a back face of the substrate, and an exposure device configured to expose the resist, the polishing treatment device including a holding rotator configured to rotate the substrate in a horizontal posture, a heating member configured to heat the substrate, and a polisher having a resin body where abrasive grains are distributed and configured to polish the back face of the substrate in a chemo-mechanical grinding manner by contacting against the back face of the substrate rotating while being heated.

The substrate treating system according to the aspect of the present invention includes the polishing treatment device (the holding rotator, the polisher, and the heating member) and the coating device. The polisher has a resin body in which abrasive grains are distributed. The polisher polishes the back face of the substrate in the chemo-mechanical grinding manner by contacting against the back face of the rotating substrate. When such polishing is performed, the substrate is heated with the heating member. When the substrate is heated, a polishing rate can increase. This can shorten time for polishing treatment. Moreover, with the polishing treatment device and the coating device, the front face of the substrate is coated with the resist, and the polishing is performed to the back face of the substrate. This achieves sufficient flatness of the substrate coated with the resist, whereby the defocus drawback of the exposure device can be overcome.

### Advantageous Effects of Invention

With the polishing method and the substrate treating system according to the aspects of the present invention, a time for polishing treatment can be shortened.

### BRIEF DESCRIPTION OF DRAWINGS

FIG. 1 is a plan view of a substrate treating system according to a first embodiment.

FIG. 2 is a plan view of a polishing treatment device according to the first embodiment.

FIGS. 3(a) to 3(d) each illustrate an inversion unit.

FIG. 4 is a side view of a polishing unit.

FIG. 5(a) is a plan view of a holding rotator, and FIG. 5(b) is a longitudinal sectional view of the construction of the holding rotator partially enlarged.

FIG. 6 illustrates a polishing mechanism of the polishing unit.

FIG. 7 illustrates an inspecting unit.

FIG. 8 is a flow chart illustrating operation of the polishing treatment device according to the first embodiment.

FIG. 9(a) is a longitudinal sectional view schematically illustrating a substrate prior to an etching step, FIG. 9(b) is a longitudinal sectional view schematically illustrating the substrate after the etching step (prior to back polishing step), and FIG. 9(c) is a longitudinal sectional view schematically illustrating the substrate after the back polishing step.

FIG. 10 is a flow chart illustrating details of a wet-etching step.

FIG. 11 illustrates a relationship between a heating temperature and a polishing rate of the substrate.

FIG. 12 is a flow chart showing procedures of a substrate cleaning step.

FIG. 13 is a plan view of a coating device.

FIG. 14 is a plan view of a treating device and an exposure device.

FIG. 15 is a plan view of a developing device.

FIG. 16 is a plan view of a substrate treating system according to a second embodiment.

FIG. 17 illustrates a preferred construction of a polishing mechanism of a polishing unit according to a third embodiment.

FIG. 18 is a longitudinal cross-sectional view of a polishing head according to the third embodiment.

FIG. 19 is a bottom view of the polishing head according to the third embodiment.

FIG. 20 is a longitudinal cross-sectional view of a polishing head according to a fourth embodiment.

FIG. 21 is a bottom view of the polishing head according to the fourth embodiment.

FIG. 22 is a longitudinal cross-sectional view of a polishing head according to a fifth embodiment.

FIG. 23 is a bottom view of the polishing head according to the fifth embodiment.

FIG. 24 is a flow chart illustrating operation of a substrate treating apparatus according to a sixth embodiment.

FIG. 25 illustrates a relationship between a heating temperature of a substrate and a contact pressure (pushing pressure) of a polisher according to a seventh embodiment.

FIG. 26 is a side view illustrating a polishing unit according to an eighth embodiment.

FIG. 27 is a side view illustrating a liquid treating unit according to the eighth embodiment.

FIGS. 28(a) and 28(b) each illustrate a heater for heating a polisher according to one modification.

FIG. 29 illustrates a relationship between a combination of heating members and a heating temperature of a substrate according to the modification.

FIGS. 30(a) and 30(b) are each a plan view of a substrate treating system according to the modification.

### FIRST EMBODIMENT

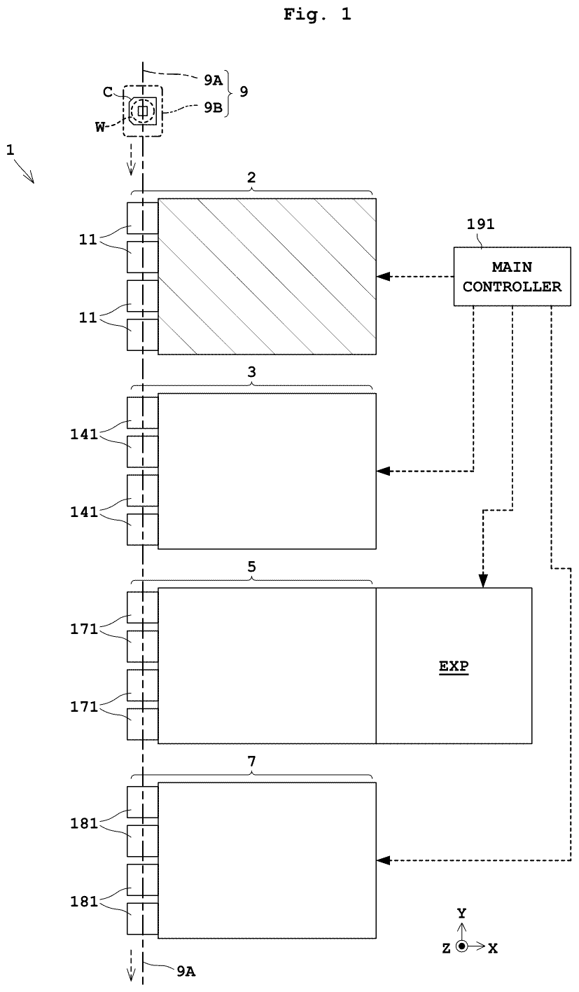

A first embodiment of the present invention will now be described with reference to the drawings. FIG. 1 is a plan view illustrating a configuration of a substrate treating system 1 according to the first embodiment.

### (1) Configuration of Substrate Treating System 1

Reference is made to FIG. 1. The substrate treating system 1 includes a polishing treatment device 2, a coating device 3, a treating device 5, an exposure device EXP, a developing device 7, and a carrier transport device 9. The devices each will be sequentially described.

The carrier transport device 9 transports a carrier C to the polishing treatment device 2, the coating device 3, the treating device 5 (exposure device EXP), and the developing device 7 in this order. The carrier transport device 9 includes a rail 9A and a transport vehicle 9B. The rail 9A is provided adjacent to the ceiling of a room, for example. The rail 9A may pass above carrier platforms 11, 141, 171, and 181, which are to be mentioned later. The transport vehicle 9B moves while being guided on the rail 9A. The transport vehicle 9B includes a gripper for gripping the carrier C and an electric motor, neither of which is not shown. The electric motor drives the gripper or moves a position of the transport vehicle 9B. Examples of the transport vehicle 9B include an overhead hoist transport (OHT). Here, the rail 9A may be provided on the floor of the room. Moreover, the rail 9A may be a virtual rail on a computer.

### (1-1) Configuration of Polishing Treatment Device 2

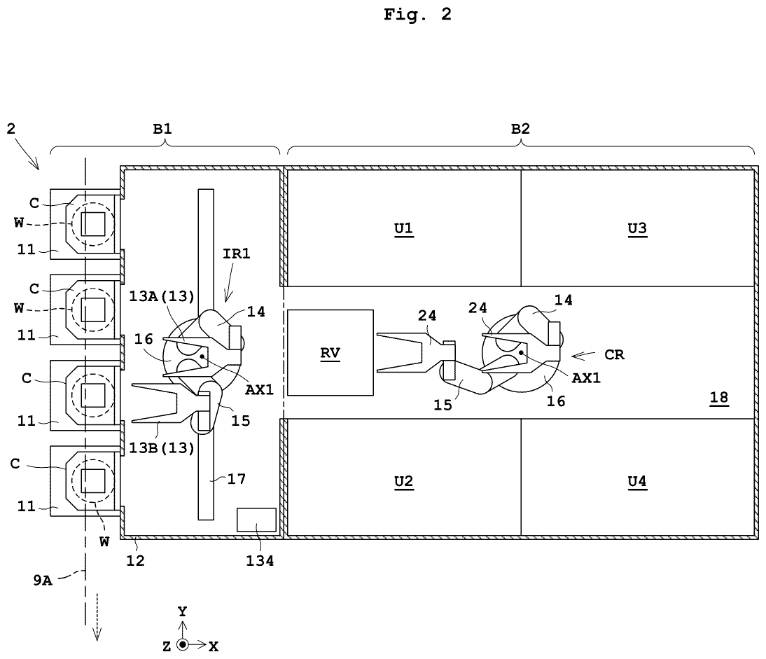

Reference is made to FIG. 2. The polishing treatment device 2 includes an indexer block B1 and a treating block B2. Here, the block is also called an area.

The indexer block B1 includes a plurality of (e.g., four) carrier platforms 11 and an indexer robot IR1. The four carrier platforms 11 are arranged on an outer face of a housing 12. The four carrier platforms 11 are each used for placing a carrier C thereon. The carrier C accommodates a plurality of substrates W. Each of the substrates W in the carrier C is in a horizontal posture while a device face thereof is directed upward (faces upward). For example, a FOUP (Front Open Unified Pod) or SMIF (Standard Mechanical Interface) pod, or an open cassette is used as the carrier C. The substrate W is a silicon substrate, and formed in a disk shape, for example.

The indexer robot IR1 takes a substrate W from the carrier C placed on the carrier platform 11, and also accommodates a substrate W into the carrier C. The indexer robot IR1 is arranged inside of the housing 12. The indexer robot IR1 includes two hands 13 (13A, 13B), two articulated arms 14, 15, a lifting and lowering board 16, and a guide rail 17. The two hands 13 each hold a substrate W. A first hand 13A is connected to a front end of the articulated arm 14. A second hand 13B is connected to a front end of the articulated arm 15.

The two articulated arms 14 and 15 are each of a SCARA type, for example. Each of the two articulated arms 14 and 15 has a proximal end attached to the lifting and lowering board 16. The lifting and lowering board 16 is configured so as to be extendible and contractible in an up-down direction. Accordingly, the two hands 13 and the two articulated arms 14 and 15 are moved upward and downward. The lifting and lowering board 16 is rotatable around a central axis AX1 extending in an up-down direction. This achieves changing of orientation of the two hands 13 and the two articulated arms 14 and 15. The lifting and lowering board 16 of the indexer robot IR1 is movable along the guide rail 17 extending in a Y-direction.

The indexer robot IR1 includes a plurality of electric motors. The indexer robot IR1 is driven by the plurality of electric motors. The indexer robot IR1 transports substrates W between the carrier C placed on each of the four the carrier platforms 11 and an inversion unit RV mentioned later.

The treating block B2 includes a transportation space 18, a substrate transporting robot CR, the inversion unit RV, and a plurality of (e.g., eight) treating units (treatment chamber) U1 to U4. In FIG. 2, the treating units U1 to U4 are formed in two layers in the up-down direction, for example. The treating unit U1 is an inspecting unit 20. The treating units U2, U3, and U4 each are a polishing unit 22. The number and types of the treating units are appropriately variable.

The transportation space 18 has the substrate transporting robot CR and the inversion unit RV arranged therein. The inversion unit RV is arranged between the indexer robot IR1 and the substrate transporting robot CR. The treating units U1 and U3 are arranged in a row along the transportation space 18 in an X-direction. Moreover, the treating units U2 and U4 are arranged in a row along the transportation space 18 in the X-direction. The transportation space 18 is arranged between the treating units U1, U3 and the treating units U2, U4.

The substrate transporting robot CR is constructed in substantially the same manner as the indexer robot IR1. That is, the substrate transporting robot CR includes two hands 24. Here, the other constructions of the substrate transporting robot CR have the same numerals as those of the indexer robot IR1. A lifting and lowering board 16 of the substrate transporting robot CR is fixed to the floor, which differs from the lifting and lowering board 16 of the indexer robot IR1. On the other hand, the lifting and lowering board 16 of the substrate transporting robot CR includes a guide rail extending in the X-direction, and is movable in the X-direction. Such construction may be adopted. The substrate transporting robot CR transports a substrate W between the inversion unit RV and the eight treating units U1 to U4.

### (1-1-1) Inversion Unit RV

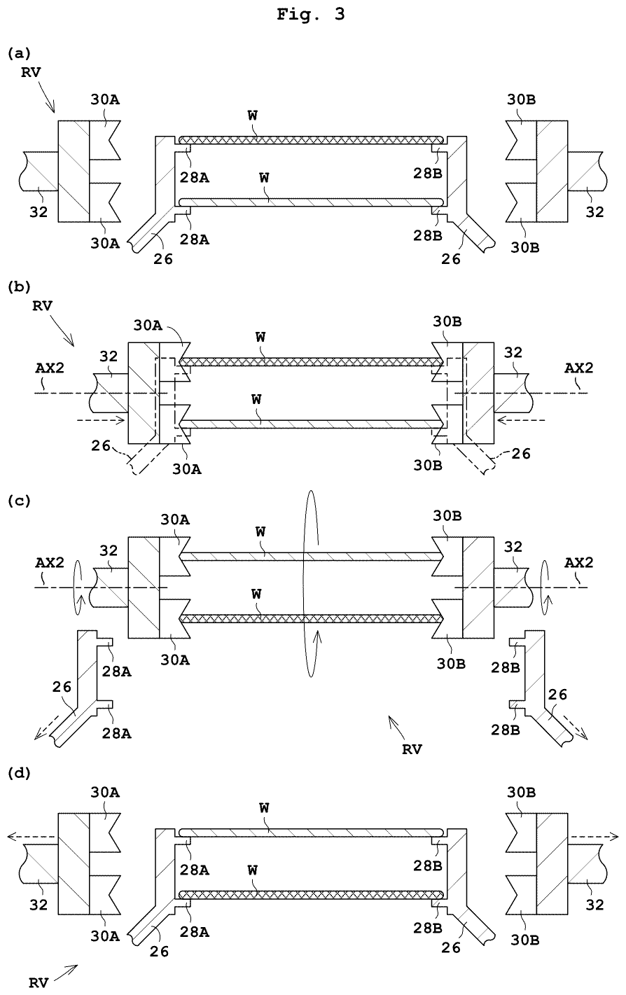

FIGS. 3(a) to 3(d) are each an explanatory view of the inversion unit RV. The inversion unit RV includes supporting members 26, mount members 28A, 28B, grasping members 30A, 30B, slide shafts 32, and a plurality of electric motors (not shown). Right and left supporting members 26 have the mount members 28A and 28B, respectively. Moreover, right and left slide shafts 32 have the grasping members 30A and 30B, respectively. The electric motors drive the supporting members 26 and the slide shafts 32. Here, the mount members 28A and 28B and the grasping members 30A and 30B are positioned so as not to interfere with each other.

Reference is made to FIG. 3(a). A substrate W, transported by the indexer robot IR1, for example, is placed on the mount members 28A and 28B. Reference is made to FIG. 3(b). The right and left slide shafts 32 approach each other along a horizontal axis AX2. Accordingly, the grasping members 30A and 30B sandwich two substrates W individually. Reference is made to FIG. 3(c). Then, the right and left mount members 28A and 28B move downward and away from each other. Then, the grasping members 30A and 30B rotate by 180 degrees around the horizontal axis AX2. This reverses each of the substrates W.

Reference is made to FIG. 3(d). Then, the right and left mount members 28A and 28B move upward while approaching each other. Then, the right and left slide shafts 32 move away from each other along the horizontal axis AX2. Accordingly, the grasping members 30A, 30B release the two substrates W, and the two substrates W are placed on the mount members 28A, 28B. In FIGS. 3(a) to 3(d), the inversion unit RV can reverse the two substrates W. Alternatively, the inversion unit RV may be configured to be capable of reversing three or more substrates W.

### (1-1-2) Polishing Unit 22

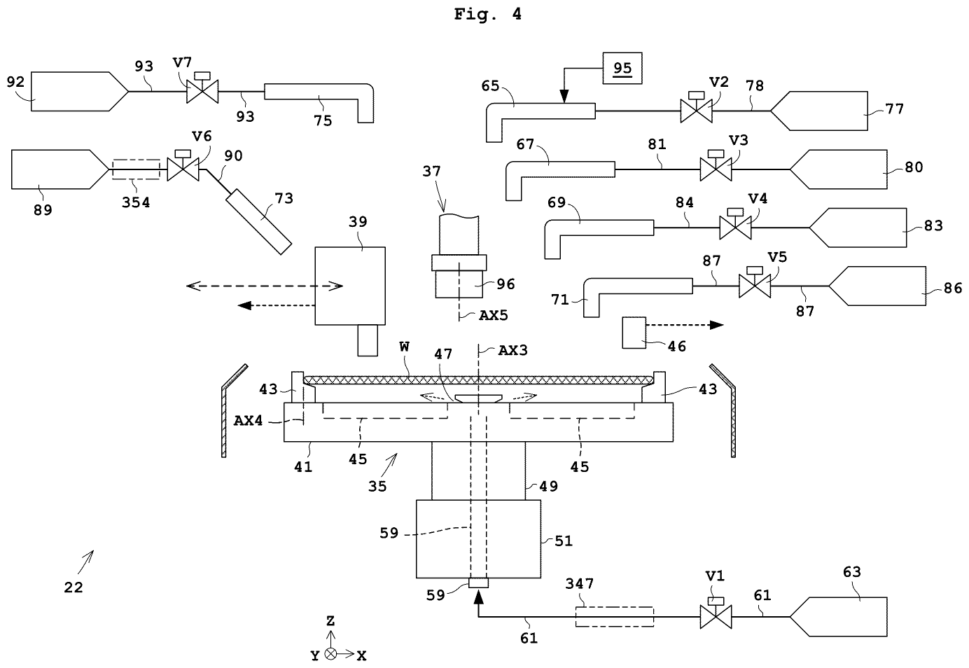

FIG. 4 shows the polishing unit 22. The polishing unit 22 includes a holding rotator 35, a polishing mechanism 37, and a substrate thickness measuring device 39. The holding rotator 35 corresponds to the holding rotator in the present invention.

The holding rotator 35 holds one substrate W whose back face is directed upward in a horizontal posture, and rotates the held substrate W. Here, the back face of the substrate W is a face where no electronic circuits are formed, which is opposite to a front face of the substrate W as a face (device face) where electronic circuits are formed. The device face of the substrate W held by the holding rotator 35 is directed downward.

The holding rotator 35 includes a spin base 41, six holding pins 43, a hot plate 45, and a gas ejection port 47. The spin base 41 is formed in a disk shape, and is arranged in a horizontal posture. A rotary axis AX3, extending in the up-down direction, passes the center of the spin base 41. The spin base 41 is rotatable around the rotary axis AX3.

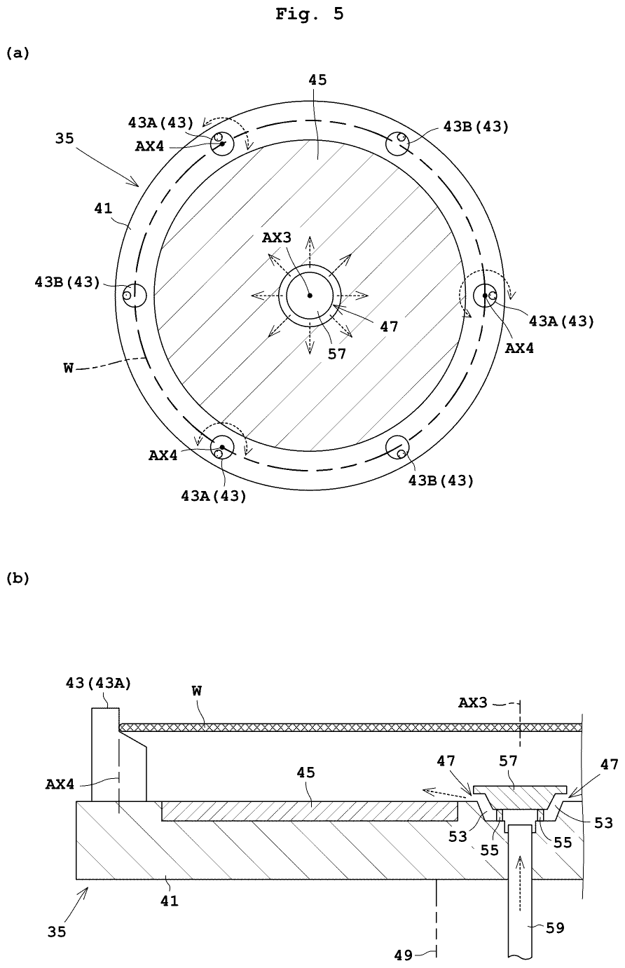

FIG. 5(a) is a plan view of the spin base 41 and the six holding pins 43 of the holding rotator 35. The six holding pins 43 are provided on a top face of the spin base 41. The six holding pins 43 are provided in a ring shape so as to surround the rotary axis AX3. Moreover, the six holding pins 43 are provided at equal intervals near an outer edge of the spin base 41. The six holding pins 43 cause the substrate W to be placed apart from the spin base 41 and the hot plate 45 mentioned later. Moreover, the six holding pins 43 are configured so as to sandwich a side face of the substrate W. That is, the six holding pins 43 can hold the substrate W while the substrate W is apart from the top face of the spin base 41.

The six holding pins 43 are divided into three holding pins 43A that rotate, and three holding pins 43B that do not rotate. The three holding pins 43A are rotatable around a rotary axis AX4 extending in the up-down direction. The three holding pins 43A each rotate around the rotary axis AX4, thereby holding the substrate W and releasing the held substrate W. The holding pins 43A each rotate around the rotary axis AX4 by magnetic suction force or repulsion by a magnet, for example. The number of holding pins 43 is not limited to six, and the number only needs to be three or more. The substrate W may be held by three or more holding pins 43 including a holding pin 43A that rotates and a holding pin 43B that does not rotate.

The hot plate 45 is provided on the top face of the spin base 41. The hot plate 45 includes therein an electric heater having a nichrome wire, for example. The hot plate 45 is formed in a toroidal and disk shape. The hot plate 45 heats the substrate W with radiant heat. Moreover, the hot plate 45 heats gas ejected from the gas ejection port 47, mentioned later, thereby heating the substrate W through the gas. A temperature sensor 46 of a non-contact type determines a temperature of the substrate W. The temperature sensor 46 includes a detecting element configured to detect infrared rays emitted from the substrate W. Here, the hot plate 45 corresponds to the heating member in the present invention. Moreover, in the embodiment 1, the polishing unit 22 does not include heaters 347, 354 (see FIG. 4) mentioned later.

A shaft 49 is provided on a lower face of the spin base 41. A rotating mechanism 51 includes an electric motor. The rotating mechanism 51 rotates the shaft 49 around the rotary axis AX3. That is, the rotating mechanism 51 rotates the substrate W, held by the six holding pins 43 (specifically, three holding pins 43A) provided on the spin base 41, around the rotary axis AX3.

Reference is made to FIG. 4 and FIG. 5(b). The gas ejection port 47 is opened in the top face of the spin base 41 and is provided at a center portion of the spin base 41. A flow path 53 whose upper part is opened is provided at the center of the spin base 41. Moreover, an ejection member 57 is provided in the flow path 53 via a plurality of spacers 55. The gas ejection port 47 is configured by a ring opening that is formed by a gap between the ejection member 57 and the flow path 53.

A gas supplying pipe 59 is provided along the rotary axis AX3 so as to pass through the shaft 49 and the rotating mechanism 51. A gas pipe 61 feeds gas (inert gas such as nitrogen gas) from a gas supplying source 63 to the gas supplying pipe 59. An on-off valve V1 is provided on the gas pipe 61. The on-off valve V1 performs and stops supply of the gas. When the on-off valve V1 is opened, the gas ejection port 47 ejects gas. When the on-off valve V1 is closed, the gas ejection port 47 does not eject gas. The gas ejection port 47 ejects gas in such a manner that the gas flows in a gap between the substrate W and the spin base 41 from a portion adjacent to the center of the substrate W toward the outer edge of the substrate W.

The following describes a construction for supplying a chemical liquid, a rinse liquid, and gas. The polishing unit 22 includes a first chemical liquid nozzle 65, a second chemical liquid nozzle 67, a first cleaning liquid nozzle 69, a second cleaning liquid nozzle 71, a rinse liquid nozzle 73, and a gas nozzle 75.

The first chemical liquid nozzle 65 is connected to a chemical liquid pipe 78 that feed a first chemical liquid from a first chemical liquid supplying source 77. The first chemical liquid is, for example, hydrofluoric acid (HF). An on-off valve V2 is provided on the chemical liquid pipe 78. The on-off valve V2 performs and stops supply of the first chemical liquid. When the on-off valve V2 is opened, the first chemical liquid is supplied from the first chemical liquid nozzle 65. Moreover, when the on-off valve V2 is closed, supply of the first chemical liquid from the first chemical liquid nozzle 65 stops.

The second chemical liquid nozzle 67 is connected to a chemical liquid pipe 81 that feed a second chemical liquid from a second chemical liquid supplying source 80. The second chemical liquid is, for example, a mixed liquid of hydrofluoric acid (HF) and nitric acid (HNO₃), tetramethylammonium hydroxide (TMAH), or hot diluted ammonia water (hot-dNH₄OH). An on-off valve V3 is provided on the chemical liquid pipe 81. The on-off valve V3 performs and stops supply of the second chemical liquid. Here, the first chemical liquid and the second chemical liquid correspond to the etching solution in the present invention.

The first cleaning liquid nozzle 69 is connected to a cleaning liquid pipe 84 that feed a first cleaning liquid from a first cleaning liquid supplying source 83. The first cleaning liquid is, for example, SC2 or SPM. Here, SC2 is a mixed liquid of hydrochloric acid (HCl), hydrogen peroxide (H₂O₂), and water. SPM is a mixed liquid of sulfuric acid (H₂SO₄) and hydrogen peroxide water (H₂O₂). An on-off valve V4 is provided on the cleaning liquid pipe 84. The on-off valve V4 performs and stops supply of the first cleaning liquid.

The second cleaning liquid nozzle 71 is connected to a cleaning liquid pipe 87 that feed a second cleaning liquid from a second cleaning liquid supplying source 86. The second cleaning liquid is, for example, SC1. SC1 is a mixed liquid of ammonia, hydrogen peroxide water (H₂O₂), and water. An on-off valve V5 is provided on the cleaning liquid pipe 87. The on-off valve V5 performs and stops supply of the second cleaning liquid.

The rinse liquid nozzle 73 is connected to a rinse liquid pipe 90 that feeds a rinse liquid from a rinse liquid supplying source 89. The rinse liquid is, for example, pure water like deionized water (DIW) or carbonated water. An on-off valve V6 is provided on the rinse liquid pipe 90. The on-off valve V6 performs and stops supply of the rinse liquid.

The gas nozzle 75 is connected to a gas pipe 93 that feeds gas from a gas supplying source 92. The gas is, for example, inert gas like nitrogen gas. An on-off valve V7 is provided on the gas pipe 93. The on-off valve V7 performs and stops supply of the gas.

The first chemical liquid nozzle 65 is moved by a nozzle moving mechanism 95 in a horizontal direction. The nozzle moving mechanism 95 includes an electric motor. The nozzle moving mechanism 95 may rotate the first chemical liquid nozzle 65 around a vertical axis (not shown) set in advance. Moreover, the nozzle moving mechanism 95 may move the first chemical liquid nozzle 65 in the X-direction and the Y-direction. Moreover, the nozzle moving mechanism 95 may move the first chemical liquid nozzle 65 in the up-down direction (Z-direction). Similar to the first chemical liquid nozzle 65, the five nozzles 67, 69, 71, 73, and 75 each may be moved by the nozzle moving mechanism (not shown).

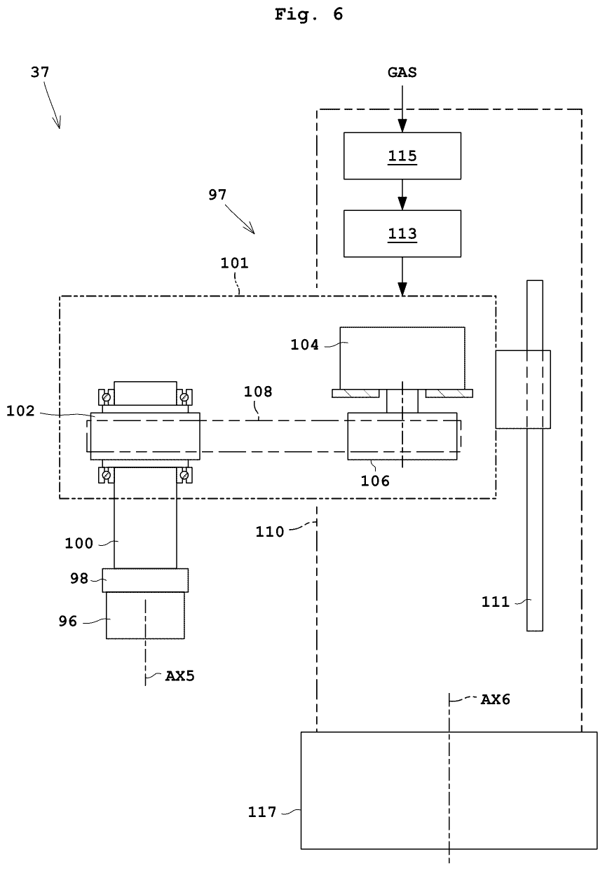

The following describes the configuration of the polishing mechanism 37. The polishing mechanism 37 polishes the back face of the substrate W. FIG. 6 is a side view of the polishing mechanism 37. The polishing mechanism 37 includes a polisher 96 and a polisher moving mechanism (head drive mechanism) 97. The polisher moving mechanism 97 includes an attachment member 98, a shaft 100, and an arm 101.

The polisher (grinder) 96 polishes the back face of the substrate W in a dry chemo-mechanical grinding (CMG) manner. The polisher 96 is formed in a cylindrical shape. The polisher 96 has a resin body in which abrasive grains are distributed. In other words, the polisher 96 is formed by fixing the abrasive grains (polishing agent) with a resin binder. An oxide such as cerium oxide or silica is used as the abrasive grains. It is preferred that the abrasive grain has an average particle size of 10 μm or less. Thermosetting resin such as epoxy resin and phenol resin is used for the resin body and resin binder. Moreover, thermoplastics such as ethyl cellulose may be used for the resin body and resin binder. In this case, polishing is performed such that the thermoplastics is not softened.

Now description will be made of the chemo-mechanical grinding (CMG). In the CMG, grinding is considered to be performed by the following principle. That is, local high temperatures and high pressure in the vicinity of the abrasive grain occur due to contact of the abrasive grain like cerium oxide and an object, leading to generation of a solid phase reaction between the abrasive grain and the object to form silicates. As a result, a surface layer of the object is softened, and the softened surface layer is mechanically removed by the abrasive grains. Here, examples of the polishing include a chemical mechanical polishing (CMP) manner. In this manner, a slurry solution is supplied to a pad which is brought into contact with the object, and the abrasive grains contained in the slurry solution are kept on an uneven surface of the pad to perform chemical mechanical polishing. The present invention adopts the CMG manner.

The polisher 96 is attachable to and detachable from the attachment member 98 via a screw, for example. The attachment member 98 is fixed to a lower end of the shaft 100. A pulley 102 is fixed to the shaft 100. An upper end of the shaft 100 is accommodated in the arm 101. That is, the polisher 96 and the attachment member 98 are attached to the arm 101 via the shaft 100.

An electric motor 104 and a pulley 106 are arranged within the arm 101. The pulley 106 is connected to a rotation output shaft of the electric motor 104. A belt 108 passes over the two pulleys 102 and 106. The pulley 106 is rotated by the electric motor 104. Rotation of the pulley 106 is transmitted to the pulley 102 and the shaft 100 by the belt 108. Accordingly, the polisher 96 rotates around a vertical axis AX5.

Moreover, the polisher moving mechanism 97 includes a lifting mechanism 110. The lifting mechanism 110 includes a guide rail 111, an air cylinder 113, and an electropneumatic regulator 115. A proximal end of the arm 101 is connected to the guide rail 111 so as to be movable upward and downward. The guide rail 111 guides the arm 101 in the up-down direction. The air cylinder 113 moves the arm 101 upward and downward. The electropneumatic regulator 115 supplies gas, such as air with pressure set in accordance with an electrical signal from a controller 134 mentioned later, to the air cylinder 113. Now, the lifting mechanism 110 may include a linear actuator, instead of the air cylinder 113, that is driven by an electric motor.

Moreover, the polisher moving mechanism 97 further includes an arm rotating mechanism 117. The arm rotating mechanism 117 includes an electric motor. The arm rotating mechanism 117 rotates the arm 101 and the lifting mechanism 110 around a vertical axis AX6. That is, the arm rotating mechanism 117 rotates the polisher 96 around the vertical axis AX6.

The polishing unit 22 includes the substrate thickness measuring device 39. The substrate thickness measuring device 39 measures a thickness of the substrate W held by the holding rotator 35. The substrate thickness measuring device 39 is configured to emit light in a wavelength range (e.g., 1100 nm to 1900 nm) that is transparent to the substrate W from a light source to a mirror and the substrate W through an optical fiber. Moreover, the substrate thickness measuring device 39 is configured to detect returned light caused by interference of reflected light by the mirror, reflected light reflected on the upper surface of the substrate W, and the reflected light reflected on the lower surface of the substrate W with use of light receiving elements. Then, the substrate thickness measuring device 39 generates a spectral interference waveform representing a relationship between the wavelength of the return light and light intensity, and analyzes the spectral interference waveform to measure a thickness of the substrate W. The substrate thickness measuring device 39 is a known device. The substrate thickness measuring device 39 may be configured so as to be movable by a moving mechanism not shown between a standby position out of the substrate W and a measuring position above the substrate W.

### (1-1-3) Inspecting Unit 20

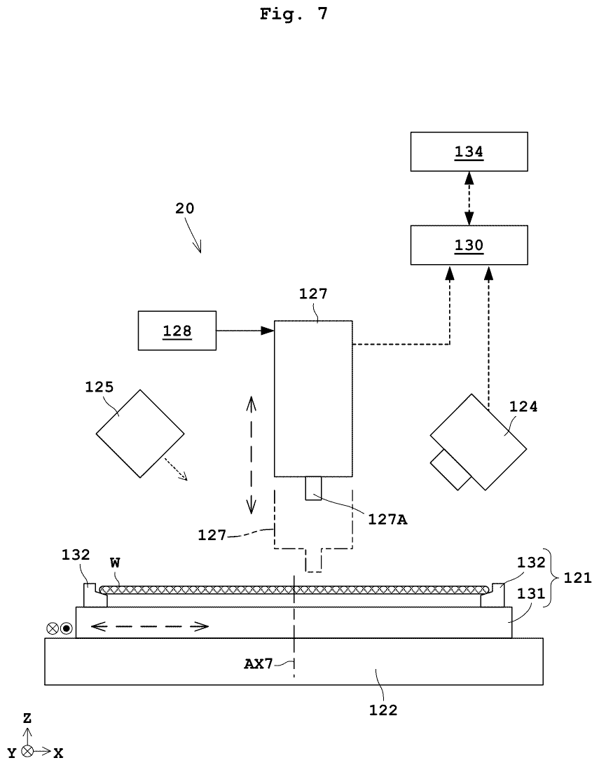

FIG. 7 is a side view of the inspecting unit 20. The inspecting unit 20 includes a stage 121, an XY-direction moving mechanism 122, a camera 124, a lighting portion 125, a laser scanning confocal microscope 127, a lifting mechanism 128, and an inspection controller 130.

The stage 121 supports the substrate W, whose back face is directed upward, in a horizontal posture. The stage 121 includes a disk base member 131 and six support pins 132, for example. The six support pins 132 are provided in a ring shape around a central axis AX7 of the base member 131. Moreover, the six support pins 132 are arranged at equal intervals in a circumferential direction. With such a construction, the six support pins 132 can support the outer edge of the substrate W while the substrate W is separated from the base member 131. Moreover, the XY-direction moving mechanism 122 moves the stage 121 in the XY-direction (horizontal direction). The XY-direction moving mechanism 122 includes, for example, two linear actuators each driven by an electric motor.

The camera 124 takes a picture of the back face of the substrate W. The camera 124 includes an image sensor such as a charge-coupled device (CCD) or a complementary metal-oxide semiconductor (CMOS). The lighting portion 125 emits light to a back face of a substrate W. This allows easy observation of a scratch generated on the back face of the substrate W, for example.

The laser scanning confocal microscope 127 is hereunder called a “laser microscope 127”. The laser microscope 127 includes a confocal optical system having a laser light source, an objective lens 127A, an imaging lens, an optical sensor, and a confocal pinhole. The laser microscope 127 captures a plane image by scanning the laser light source in the XY-direction (horizontal direction). Moreover, the laser microscope 127 captures plane images by moving the objective lens 127A in the Z-direction (height direction) relative to the object to be observed. As a result, the laser microscope 127 captures a three-dimensional image (a plurality of plane images) containing a three-dimensional shape. Here, the laser microscope 127 is called a three-dimensional shape measuring device.

The laser microscope 127 captures a three-dimensional image of any scratch generated on the back face of the substrate W. For example, a controller mentioned later determines a depth of the scratch from the three-dimensional shape of the scratch in the captured three-dimensional image. The lifting mechanism 128 moves the laser microscope 127 upward and downward in the up-down direction (Z-direction). The lifting mechanism 128 is formed by a linear actuator driven by an electric motor.

The inspection controller 130 includes one or more processors like a central processing unit (CPU), and a memory unit (not shown), for example. The inspection controller 130 controls each component of the inspecting unit 20. The memory unit of the inspection controller 130 includes at least one selected from a read-only memory (ROM), a random-access memory (RAM), and a hard disk. The memory unit of the inspection controller 130 stores computer program for operating the inspecting unit 20, observed images, an extraction result of the scratch, and a three-dimensional image.

Moreover, the polishing treatment device 2 further includes the controller 134 communicably connected to the inspection controller 130, and a memory unit (not shown). The controller 134 includes one or more processors like a central processing unit (CPU), for example. The controller 134 controls components of the polishing treatment device 2. Moreover, the memory unit of the controller 134 includes at least one selected from a read-only memory (ROM), a random-access memory (RAM), and a hard disk. The memory unit of the controller 134 stores computer programs and the like for operating the polishing treatment device 2.

### (1-2) Operation of Polishing Treatment Device 2

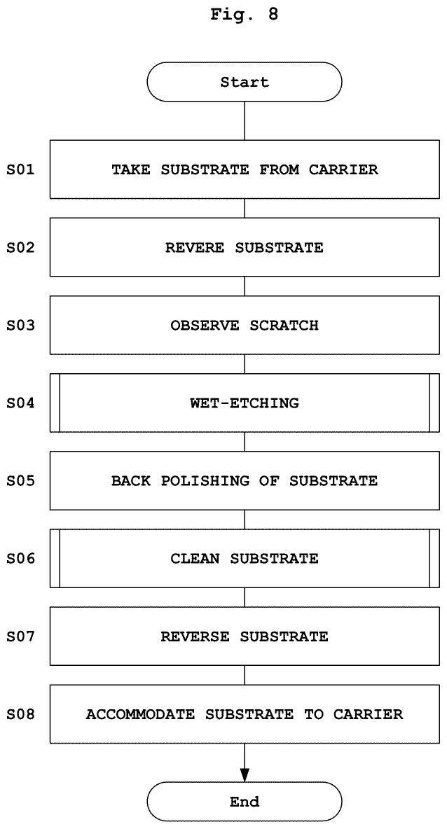

Description will be given of operation of the polishing treatment device 2 with reference to FIG. 8 before description of the construction of the other devices 3, 5, 7, and the EXP of the substrate treating system 1.

[Step S01] Taking Substrate W from Carrier C

Carriers C are placed on the given carrier platforms 11, respectively. The indexer robot IR1 takes a substrate W from one of the carriers C, and transports the taken substrate W to the inversion unit RV. At this time, the device face of the substrate W is directed upward while the back face of the substrate W is directed downward.

### [Step S02] Reversing Substrate W

When one substrate W or two substrates W are placed on the mount members 28A, 28B by the indexer robot IR1, the inversion unit RV reverses the one substrate W or the two substrates W as shown in FIGS. 3(a) to 3(d). Accordingly, the back faces of the substrates W are each directed upward.

The substrate transporting robot CR takes the substrate W from the inversion unit RV, and transports the taken substrate W to one of the two inspecting units 20. The substrate W whose back face is directed upward is placed on the stage 121 of the inspecting unit 20 shown in FIG. 7.

### [Step S03] Observing Scratch

The inspecting unit 20 performs inspection to the back face of the substrate W. The inspecting unit 20 detects a scratch, particles, and other projections. In this embodiment, description is particularly made of a case where a scratch formed on the back face of the substrate W is detected.

The lighting portion 125 emits light toward the back face of the substrate W in the inspecting unit 20 shown in FIG. 7. The camera 124 takes a picture of the back face of the substrate W to which light is emitted, thereby capturing an observed image. The camera 124 may take a picture while the XY-direction moving mechanism 122 moves the stage 121 on which the substrate W is placed. Large and small scratches appear in the captured observed image. The inspection controller 130 performs image processing on the observed image, and extracts one or more scratches to be polished where the reflected light is relatively strong, that is, part having luminance higher than a preset threshold. Moreover, the inspection controller 130 may extract a scratch to be polished based on a length of the scratch.

Moreover, the inspecting unit 20 measures a depth of a scratch when the scratch is detected. For example, when a plurality of scratches is detected (extracted), the inspecting unit 20 measures a depth of a representative scratch or depths of the representative scratches. The following describes measurement of the depth of the scratch.

The lifting mechanism 128 (FIG. 7) moves the laser microscope 127 downward to a preset height position. In addition, the XY-direction moving mechanism 122 moves the stage 121 in such a manner that a scratch to be measured is positioned below the objective lens 127A of the laser microscope 127. The stage 121 is moved in accordance with a coordinate of the scratch extracted in the observed image. The laser microscope 127 collects the reflected light through the objective lens 127A while irradiating the scratch (entirely or partially) and its periphery with laser light from the objective lens 127A. As a result, the laser microscope 127 captures a three-dimensional image containing a three-dimensional shape.

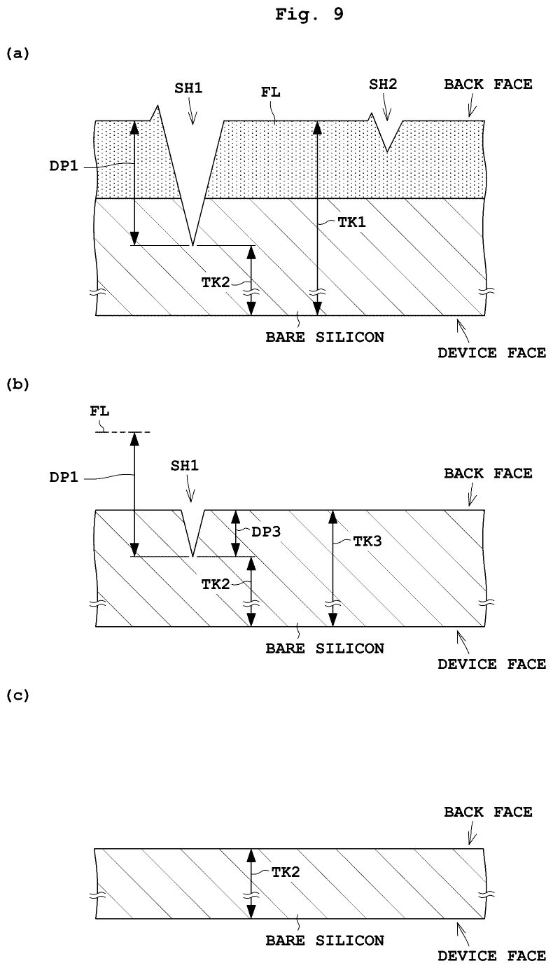

The inspection controller 130 measures a depth of the scratch by performing image processing to the three-dimensional image. FIG. 9(a) is a longitudinal sectional view for explanation of a state of the substrate W prior to an etching step. In FIG. 9(a), it is assumed that a thin film FL such as a silicon oxide film, a silicon nitride film, and polysilicon is formed on the back face of the substrate W. Moreover, it is assumed that a scratch SH1 on the left side of FIG. 9(a) reaches to bare silicon BSi. In this case, the inspection controller 130 measures a depth of the scratch SH1 (value DP1) from the three-dimensional image obtained by the laser microscope 127.

After the scratch and the like is observed, the substrate transporting robot CR transports the substrate W from the stage 121 of the inspecting unit 20 to any one of six polishing units 22 (U2 to U4). The substrate W whose back face is directed upward is placed on the holding rotator 35 of the polishing unit 22. Then, a magnet not shown causes three holding pins 43A shown in FIG. 5(a) to rotate around the rotary axis AX4. Thereby, the three holding pins 43A hold the substrate W. Here, the substrate W is held while being separated from the spin base 41 and the hot plate 45.

Then, the substrate thickness measuring device 39 measures the thickness of the substrate W prior to a next wet-etching step. A thickness TK1 of the substrate W as shown in FIG. 9(a) is obtained.

### [Step S04] Wet-Etching

When the thin film such as a silicon oxide film, a silicon nitride film, and polysilicon film is formed on the back face of the substrate W, the polisher 96 cannot polish the back face of the substrate W suitably. Some of these films are formed unintentionally in the manufacturing step of the device, while others are formed intentionally to suppress warping of the substrate W. Then, the polishing unit 22 removes a film FL formed on the back face of the substrate W by supplying a first chemical liquid (etching solution) to the back face of the substrate W.

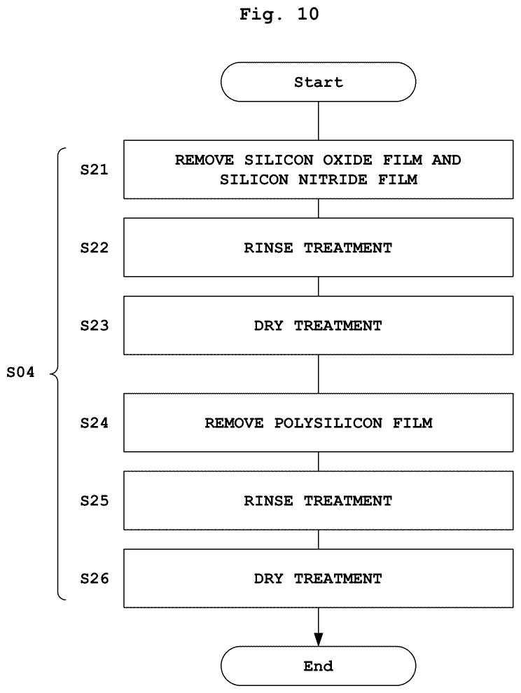

FIG. 10 is a flow chart for explanation of details of the wet-etching step in the step S04. Firstly, a silicon oxide film and a silicon nitride film are removed (step S21).

Here, the gas ejection port 47 provided at a center of the spin base 41 ejects gas. That is, the gas ejection port 47 ejects gas in such a manner that the gas flows in a gap between the substrate W and the spin base 41 from the center of the substrate W toward the outer edge of the substrate W. A device face (front face) of the substrate W faces the spin base 41. When gas is ejected from the gas ejection port 47, gas jets outward from the gap between an outer edge of the substrate W and the spin base 41. For example, the polishing scraps or a liquid such as the first chemical liquid can be prevented from adhering on the device face of the substrate W. That is, the device face can be protected. Moreover, due to a Bernoulli's effect, a force to absorb the substrate W to the spin base 41 acts.

The nozzle moving mechanism 95 moves the first chemical liquid nozzle 65 from a standby position outside of the substrate W to any treating position above the substrate W. The holding rotator 35 rotates the substrate W while holding the substrate W in a horizontal posture. Then, the first chemical liquid nozzle 65 supplies the first chemical liquid (e.g., hydrofluoric acid) to the back face of the rotating substrate W. Accordingly, the silicon oxide film and the silicon nitride film formed on the back face of the substrate W can be removed.

Here, the first chemical liquid may be supplied while the first chemical liquid nozzle 65 moves horizontally. Moreover, after the first chemical liquid nozzle 65 stops supply of the first chemical liquid, the first chemical liquid nozzle 65 is moved to the standby position outside of the substrate W.

Then, rinse treatment is performed (step S22). That is, the rinse liquid nozzle 73 supplies a rinse liquid (e.g., DIW or carbonated water) to the center of the rotating substrate W. In this way, the first chemical liquid remaining on the back face of the substrate W is washed off toward outside of the substrate. Then, dry treatment is performed (step S23). That is, the rinse liquid nozzle 73 stops supply of the rinse liquid. Then, the holding rotator 35 rotates the substrate W at high speed to dry the substrate W. At this time, the gas nozzle 75 moved above the substrate W may supply gas to the back face of the substrate W. Here, the dry treatment may be performed not by rotating the substrate W at high speed but by supplying gas from the gas nozzle 75.

After the steps S21 to S23, the polysilicon film is removed (step S24). The second chemical liquid nozzle 67 is moved from a standby position outside of the substrate W to any treating position above the substrate W. The holding rotator 35 rotates the substrate W at a preset rotation speed. Then, the second chemical liquid nozzle 67 supplies the second chemical liquid (e.g., the mixed liquid of hydrofluoric acid (HF) and nitric acid (HNO₃)) to the back face of the rotating substrate W. Accordingly, the polysilicon film formed on the back face of the substrate W can be removed.

The second chemical liquid may be supplied while the second chemical liquid nozzle 67 moves horizontally. Moreover, after the second chemical liquid nozzle 67 stops supply of the second chemical liquid, the second chemical liquid nozzle 67 is moved to the standby position outside of the substrate W.

Then, substantially similar to the case of the first chemical liquid (steps S22 and S23), rinse treatment (step S25) is performed and thereafter dry treatment (step S26) is performed. The holding rotator 35 stops rotation of the substrate W.

### [Step S05] Back Polishing of Substrate W

After the wet-etching step, the polishing unit 22 polishes the back face of the substrate W. Such polishing is performed especially when the inspecting unit 20 detects a scratch on the back face of the substrate W. Detailed description is as under.

The holding rotator 35 rotates the substrate W while holding the substrate W in a horizontal posture. The arm rotating mechanism 117 of the polishing mechanism 37 (FIG. 6) rotates the polisher 96 and the arm 101 around the vertical axis AX6. Accordingly, the polisher 96 is moved from the standby position outside of the substrate W to a preset position above the substrate W. Moreover, the electric motor 104 of the polishing mechanism 37 rotates the polisher 96 around the vertical axis AX5 (shaft 100).

Moreover, the hot plate 45 heats the substrate W with heat generated by passing current. The temperature sensor 46 of a non-contact type monitors a temperature of the substrate W. The controller 134 adjusts heat from the hot plate 45 in accordance with the temperature of the substrate W detected by the temperature sensor 46. A heating temperature of the substrate W is adjusted to a temperature higher than room temperature (e.g., 25° C.) for obtaining a high polishing rate. Note that it is preferred to adjust the heating temperature 100° C. or lower for avoiding thermal degradation of the polisher 96.

Then, the electropneumatic regulator 115 supplies gas, having pressure in accordance with the electrical signal, to the air cylinder 113. Accordingly, the air cylinder 113 moves the polisher 96 and the arm 101 downward to contact the polisher 96 against the back face of the rotating substrate W. The polisher 96 is pressed against the back face of the substrate W at preset contact pressure. This achieves polishing. When the polishing is performed, the arm rotating mechanism 117 of the polishing mechanism 37 (FIG. 6) swings the polisher 96 and the arm 101 around the vertical axis AX6. That is, the polisher 96 reciprocates repeatedly between a position adjacent to the center of the back face and a position adjacent to the outer edge of the substrate W, for example.

Now, regarding an amount of polishing in the thickness direction (Z-direction) of the substrate W, it is considered unnecessary to perform polishing as long as the substrate W satisfies a preset flatness even if a scratch exists. However, an edge of the scratch may create a new damage on the stage of the exposure device, for example. Accordingly, polishing is performed until a scratch having a preset size is eliminated.

As shown in FIG. 9(a), the depth of the scratch SH1 (value DP1) is obtained by the laser microscope 127. Accordingly, the polishing unit 22 polishes the back face of the substrate W until a thickness corresponding to the depth of the scratch SH1 (value DP1), determined by the laser microscope 127, is scraped off. The thickness corresponding to the depth of the scratch SH1 is the value DP1. Polishing is performed until the thickness of the substrate W is brought into a value TK2 (=TK1−DP1). The thickness of the substrate W is periodically measured by the substrate thickness measuring device 39. When comparison is made between a measured value and a target value (e.g., value TK2) of the substrate thickness and then if the measured value does not reach the target value, the controller 134 controls to perform polishing continuously.

Now, FIG. 9(b) is a view illustrating a state after the etching step (step S04). When the film FL is removed by the etching step, the depth of the scratch SH1 is decreased. Accordingly, an amount of polishing is made small in the up-down direction, whereas polishing is performed continuously until the thickness of the substrate W is brought into the value TK2. FIG. 9(c) is a view illustrating a state after the polishing step (step S05). Now, a scratch SH2 shown in FIG. 9(a) does not reach bare silicon. Such a scratch is removed together when the film FL such as silicon oxide film is removed.

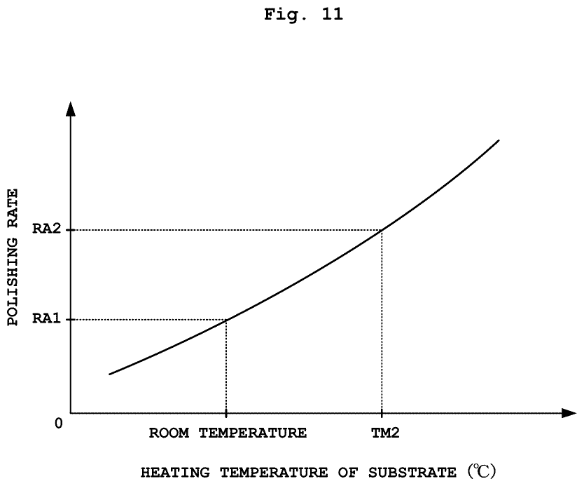

The substrate W is heated by the hot plate 45. FIG. 11 illustrates a relationship between the heating temperature and the polishing rate of the substrate W. The contact pressure of the polisher 96, the rotation speed of the substrate W and the like are constant. Here, polishing rate increases when a temperature TM2 of the substrate W becomes high relative to a case where the temperature of the substrate W is room temperature (e.g., 25° C.), for example. Accordingly, heating the substrate W by hot plate 45 can increase the polishing rate. This can shorten time for polishing treatment.

When polishing is performed, the polishing unit 22 may adjust the polishing rate by controlling the heating temperature of the substrate W by the hot plate 45. Raising and lowering the heating temperature of the substrate W allows increase and decrease of the polishing rate. The polishing rate may be adjusted prior to or during the polishing. For example, the polishing rate can be made different between the part adjacent to the center of the substrate W and the part adjacent to the outer edge of the substrate W by changing the temperature of the substrate W between the part adjacent to the center of the substrate W and the part adjacent to the outer edge of the substrate W. Now, after polishing the back face of the substrate W, the polisher 96 is moved to the standby position out of the substrate W.

### [Step S06] Cleaning Substrate W

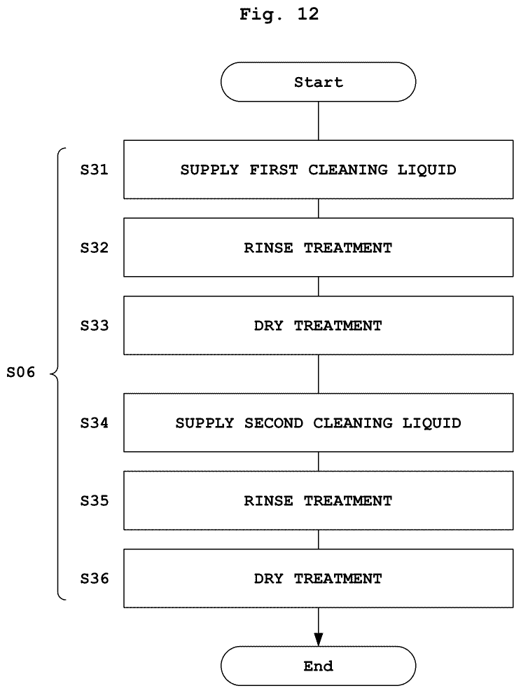

After the back face of the substrate W is polished, the back face of the substrate W is cleaned. Accordingly, polishing scraps remaining on the back face of the substrate W are removed, and metal, organic matters and particles are removed. FIG. 12 is a flow chart showing procedures of a cleaning step in the step S06.

Firstly, a first cleaning liquid is supplied to the back face of the substrate W (step S31). Detailed description is as under. The holding rotator 35 keeps holding of the substrate W. Moreover, the holding rotator 35 keeps protecting the device face of the substrate W by ejecting gas from the gas ejection port 47. The first cleaning liquid nozzle 69 is moved from a standby position outside of the substrate W to any treating position above the substrate W. The holding rotator 35 rotates the substrate W. Then, the first cleaning liquid nozzle 69 supplies the first cleaning liquid (e.g., SC2 or SPM) to the back face of the rotating substrate W. The first cleaning liquid may be supplied while the first cleaning liquid nozzle 69 moves horizontally.

After the first cleaning liquid is supplied to perform the cleaning treatment, rinse treatment is performed (step S32). That is, the rinse liquid nozzle 73 supplies a rinse liquid (DIW or carbonated water) to the center of the rotating substrate W. In this way, the first cleaning liquid remaining on the back face of the substrate W is washed off. Then, dry treatment is performed (step S33). That is, the rinse liquid nozzle 73 stops supply of the rinse liquid. Then, the holding rotator 35 rotates the substrate W at high speed to dry the substrate W. At this time, the gas nozzle 75 moved above the substrate W may supply gas to the back face of the substrate W. Here, the dry treatment may be performed not by rotating the substrate W at high speed but by supplying gas from the gas nozzle 73.

After the steps S31 to S33, a second cleaning liquid is supplied (step S34). That is, the second cleaning liquid nozzle 71 is moved from a standby position outside of the substrate W to any treating position above the substrate W. The holding rotator 35 rotates the substrate W at a preset rotation speed. Then, the second cleaning liquid nozzle 71 supplies the second cleaning liquid (e.g., SC1) to the back face of the rotating substrate W.

The second cleaning liquid may be supplied while the second cleaning liquid nozzle 71 moves horizontally. After the second cleaning liquid nozzle 71 stops supply of the second cleaning liquid, the second cleaning liquid nozzle 71 is moved to the standby position outside of the substrate W.

Then, substantially similar to the case of the first cleaning liquid (steps S32 and S33), rinse treatment (step S35) is performed and thereafter dry treatment (step S36) is performed. The holding rotator 35 stops rotation of the substrate W. Since the polishing unit 22 in this embodiment has a cleaning function, the substrate W from which polishing scraps are cleaned off can be unloaded from the polishing unit 22.

### [Step S07] Reversing Substrate W

The substrate transporting robot CR takes the substrate W from the polishing unit 22, and transports the taken substrate W to the inversion unit RV. At this time, the back face of the substrate W is directed upward while the device face of the substrate W is directed downward. When one substrate W or two substrates W are placed on the mount members 28A, 28B by the substrate transporting robot CR, the inversion unit RV reverses one substrate W or two substrates W as shown in FIGS. 3(a) to 3(d). Accordingly, the back faces of the substrates W are each directed downward.

### [Step S08] Accommodation of Substrate W to Carrier C

The indexer robot IR1 takes the substrate W from the inversion unit RV, and returns the substrate W to the carrier C.

### (1-3) Construction of Coating Device 3

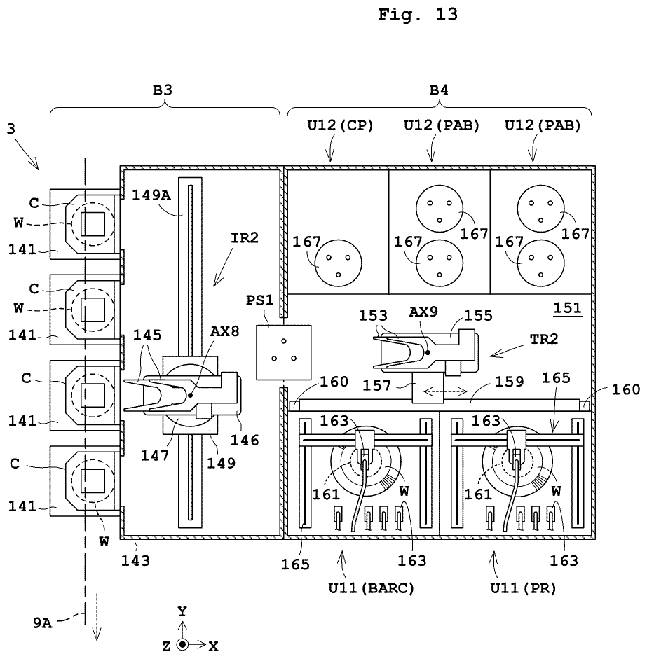

Reference is made to FIG. 13. The coating device 3 includes an indexer block B3, a coating block B4, and a substrate platform PS1. The substrate platform PS1 is located between the two blocks B3 and B4. The substrate platform PS1 places the substrates W thereon. Here, the coating device 3 may include a plurality of substrate platforms PS1.

The indexer block B3 includes a plurality of (e.g., four) carrier platforms 141 and an indexer robot IR2. The four carrier platforms 141 are arranged on an outer face of a housing 143. The four carrier platforms 141 are each used for placing a carrier C thereon.

The indexer robot IR2 is located inside of the housing 143. The indexer robot IR2 takes a substrate W from a carrier C placed on one of the carrier platforms 141, and also accommodates a substrate W into a carrier C. That is, the indexer robot IR2 loads and unloads the substrate W into and from the carrier C. Moreover, the indexer robot IR2 transports a substrate W between a carrier C placed on the carrier platform 141 and the substrate platform PS1.

The indexer robot IR2 includes two hands 145, a forward/rearward driving unit 146, a lifting/lowering rotation driving unit 147, and a horizontal drive unit 149. The two hands 145 each hold a substrate W. Moreover, each of the two hands 145 is attached to the forward/rearward driving unit 146 so as to be movable forward and rearward. The forward/rearward driving unit 146 is capable of moving the two hands 145 forward and rearward simultaneously. Moreover, the forward/rearward driving unit 146 is capable of moving the two hands 145 forward and rearward individually. The lifting/lowering rotation driving unit 147 lifts, lowers, and rotates the forward/rearward driving unit 146 to thereby lift, lower, and rotate the two hands 145. In other words, the lifting/lowering rotation driving unit 147 allows the forward/rearward driving unit 146 to move in an up-down direction (Z-direction) and to rotate the forward/rearward driving unit 146 about a vertical axis AX8.

The horizontal drive unit 149 includes a guide rail 149A extending in the Y-direction. The horizontal drive unit 149 moves the lifting/lowering rotation driving unit 147 in Y-direction where the four carrier platforms 141 are lined. Thereby, the horizontal drive unit 149 is capable of moving the two hands 145 in the Y-direction. The forward/rearward driving unit 146, the lifting/lowering rotation driving unit 147, and the horizontal drive unit 149 each include an electric motor.

The coating block B4 includes a transportation space 151, a substrate transporting robot TR2, a plurality of liquid treating units U11, and a plurality of treating units U12. The substrate transporting robot TR2 is provided in the transportation space 151. The substrate transporting robot TR2 is capable of transporting a substrate W among the substrate platform PS1 and the liquid treating units U11, and the treating units U12.

The substrate transporting robot TR2 includes two hands 153, a forward/rearward driving unit 155, a rotation driving unit 157, a horizontal drive unit 159, and a lifting/lowering driving unit 160. The two hands 153 each hold a substrate W. The forward/rearward driving unit 155 moves the two hands 153 forward and rearward in a manner similar to the forward/rearward driving unit 146 of the indexer robot IR2. The rotation driving unit 157 rotates the forward/rearward driving unit 155 around a vertical axis AX9. This achieves changing of orientation of the two hands 153. The horizontal drive unit 159 moves the rotation driving unit 157 in the X-direction. Moreover, the lifting/lowering driving unit 160 moves the horizontal drive unit 159 in the Z-direction. The two hands 153 are moved by the horizontal drive unit 159 and the lifting/lowering driving unit 160 in the XZ-direction. The forward/rearward driving unit 155, the lifting/lowering rotation driving unit 157, the horizontal drive unit 159, and the lifting/lowering driving unit 160 each include an electric motor.

The transportation space 151 is configured to extend in the X-direction in plan view. The liquid treating units U11 are provided along the transportation space 151. For example, when four liquid treating units U11 are provided, the four liquid treating units U11 are arranged in two stages in the up-down direction (Z-direction), each stage having two liquid treating units U11 in the horizontal direction (X-direction).

As shown in FIG. 13, the liquid treating units U11 includes a holding rotator 161, nozzles 163, and a nozzle moving mechanism 165. The holding rotator 161 is configured to rotate the substrate W around the vertical axis while holding the substrate W in a horizontal posture. The holding rotator 161 holds the substrate W by suction-holding a lower surface of the substrate W or sandwiching a side face of the substrate W in the horizontal direction. The holding rotator 161 includes an electric motor for rotating the substrate W. The nozzles 163 dispense a resist liquid or a chemical liquid for forming an antireflection film, for example. A pipe having an on-off valve provided thereon is connected to each of the nozzles 163. The nozzle moving mechanism 165 is configured to move the nozzles 163 to any positions. The nozzle moving mechanism 165 includes, for example, a linear actuator driven by an electric motor.

As the liquid treating unit U11, a coating unit PR configured to coat a front face of the substrate W with the resist, for example. In addition, as for the liquid treating unit U11, a coating unit BARC configured to form an antireflection film may be used, for example.

The treating units U12 are provided to face the liquid treating units U11 across the transportation space 151. The treating units U12 are provided along the transportation space 151. For example, when fifteen treating units U12 are provided, the fifteen treating units U12 are arranged in five stages in the up-down direction (Z-direction), each stage having three treating units U12 in the horizontal direction (X-direction). As for the treating unit U12, a cooling unit CP and a heat treating unit PAB are used, for example.

The cooling units CP cool the substrates W. The heat treating units PAB perform a bake treatment on a substrate W after coating. The heat treating units PAB, a post-exposure bake treatment units PEB (mentioned later), and a post-bake unit PB (mentioned later) each have a cooling function. When the substrate W is heated, the treating units U12 and treating units U22 and U32 mentioned later each include a plate 167 on which the substrate W is placed and a heater (e.g., electric heater), for example. When the substrate W is cooled, the treating units U12 and treating units U22 and U32 mentioned later each include a plate 167 and a water-cooled circulating mechanism or a Peltier element, for example.

### (1-4) Configuration of Treating Device 5 and Exposure Device EXP

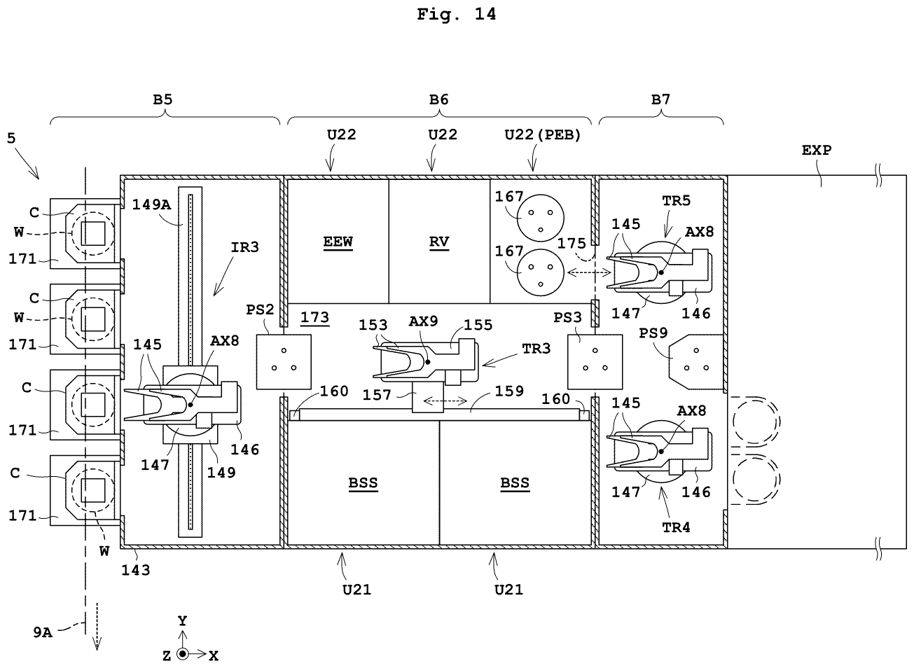

Reference is made to FIG. 14. The treating device 5 is connected to the exposure device EXP in the horizontal direction. The treating device 5 includes an indexer block B5, a treating block B6, and an interface block B7.

The indexer block B5 is configured in substantially the same manner as the indexer block B3 in the coating device 3. The indexer block B5 includes a plurality of (e.g., four) carrier platforms 171 and an indexer robot IR3. The indexer robot IR3 transports a substrate W between a carrier C placed on the carrier platform 171 and a substrate platform PS2 mentioned later. Here, the same numerals are applied to the other construction of the indexer block B5 as the constructions of the indexer block B3 in the coating device 3.

The treating block B6 includes a transportation space 173, a substrate transporting robot TR3, a plurality of liquid treating units U21, and a plurality of the treating units U22. These elements 173, TR3, U21, and U22 are arranged in the same manner as the elements 151, TR2, U11, and U12, respectively, of the coating block B4 in the coating device 3.

A back face cleaning unit BSS is used as the liquid treating unit U21. The back face cleaning unit BSS cleans a back face of the substrate W with a cleaning liquid supplied to the back face of the substrate W and a brush. The back face cleaning unit BSS includes a holding rotator, a nozzle, a brush, and a brush moving mechanism. The holding rotator rotates the substrate W around the vertical axis while holding the substrate W, whose back face is directed upward, in a horizontal posture, which is similar to the holding rotator 35 in FIG. 4. The nozzle supplies a cleaning liquid and a rinse liquid. The brush adopts a sponge brush of polyvinyl alcohol (PVA), for example. The brush moving mechanism moves the brush in the horizontal direction and the up-down direction, which is similar to the polisher moving mechanism 97 in FIG. 6.

Moreover, an edge exposing unit EEW, an inversion unit RV, and a post-exposure bake treatment unit PEB are used as the treating unit U22. The edge exposing units EEW each expose a periphery edge of a substrate W. The inversion unit RV reverses the substrate W as shown in FIGS. 3(a) to 3(d). The post-exposure bake treatment units PEB perform a heating treatment on the substrate W after exposure.

A substrate platform PS2 is provided between the indexer block B5 and the treating block B6. Moreover, a substrate platform PS3 is provided between the treating block B6 and the interface block B7. The two substrate platforms PS2 and PS3 are each configured to place a substrate W thereon. Here, a plurality of substrate platform PS2 may be provided. A plurality of substrate platform PS3 may be provided.

The substrate transporting robot TR3 is provided in the transportation space 173. The substrate transporting robot TR3 is constructed in the same manner as the substrate transporting robot TR2 in the coating device 3. The substrate transporting robot TR3 transports a substrate W among the substrate platforms PS2 and PS3, the back face cleaning unit BSS, the edge exposing unit EEW, and the inversion unit RV.

The interface block B7 loads and unloads the substrate W into and from an external exposure device EXP. The interface block B7 includes two substrate transporting robots TR4 and TR5, and a substrate platform PS9. The two substrate transporting robots TR4 and TR5 are arranged in the Y-direction. The substrate transporting robots TR4 and TR5 are each fixed on the floor without having the horizontal drive unit 149 for moving the lifting/lowering rotation driving unit 147 in the Y-direction. Except this point, the substrate transporting robots TR4 and TR5 are configured in the same manner as the indexer robot IR2 (IR3).

The substrate transporting robot TR4 is located adjacent to the liquid treating unit U21. The substrate transporting robot TR4 transports substrates W among the substrate platform PS3, the exposure device EXP, and the substrate platform PS9. Moreover, the substrate transporting robot TR5 is located adjacent to the treating unit U22. The substrate transport robot TR5 transports substrates W between the substrate platform PS9 and the post-exposure bake treatment unit PEB.

The post-exposure bake treatment unit PEB is located next to the interface block B7, and has an inlet 175 for communicating with an interior space of the interface block B7. Accordingly, the substrate transport robot TR5 can transport the substrate W to the post-exposure bake treatment unit PEB in the treating block B6 not through the substrate platform PS3.

The exposure device EXP is configured to perform exposure treatment on the resist (photoresist film) coated on the front face of the substrate W. The exposure device EXP includes, for example, an irradiation system, a reflection-type mask, a mask stage, a projection optical system (reflection optical system), a substrate stage, and a stage driving unit, any of which is not shown. The irradiation system includes a light source that emits extreme ultraviolet (EUV) rays. The EUV rays have a wavelength of 13.5 nm, for example. The mask stage holds a mask. The mask has a pattern formed thereon. The projection optical system includes a plurality of multilayer mirrors. The substrate stage places the substrate W thereon. The stage drive unit includes a linear actuator driven by an electric motor for moving the substrate stage in the horizontal direction. The EUV rays emitted from the irradiation system is emitted to the resist, coated on the front face of the substrate W, through the mask and the projection optical system.

### (1-5) Construction of Developing Device 7

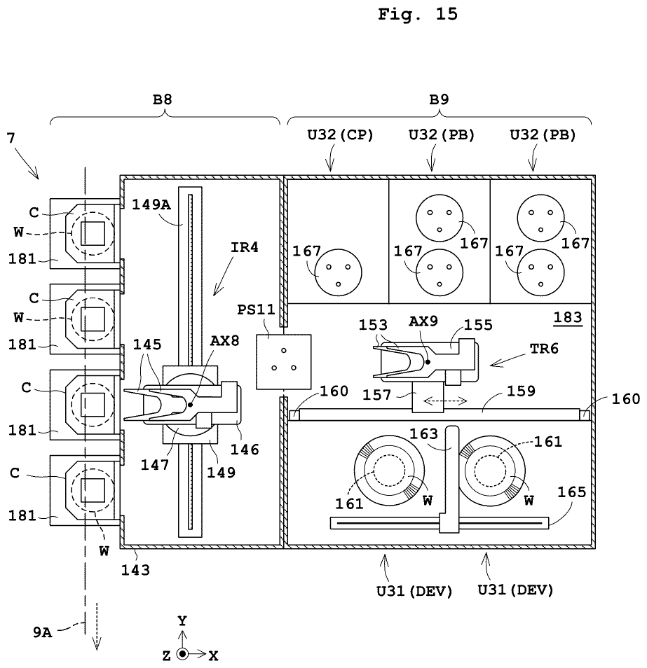

Reference is made to FIG. 15. The developing device 7 includes an indexer block B8, a developing block B9, and a substrate platform PS11. The indexer block B8 is configured in substantially the same manner as the indexer block B3 in the coating device 3. The indexer block B8 includes a plurality of (e.g., four) carrier platforms 181 and an indexer robot IR4.

The indexer robot IR4 transports a substrate W between a carrier C placed on each of the carrier platforms 181 and the substrate platform PS11. The same numerals are applied to the other construction of the carrier platform 181 and the indexer robot IR4 as the constructions of the indexer block B3 in the coating device 3. The substrate platform PS11 is provided between the indexer block B8 and the developing block B9. A plurality of substrate platform PS11 may be provided.

The developing block B9 includes a transportation space 183, a substrate transporting robot TR6, a plurality of liquid treating units U31, and a plurality of treating units U32. These elements 183, TR6, U31, and U32 are arranged in the same manner as the elements 151, TR2, U11, and U12, respectively, of the coating block B4 in the coating device 3.

A developing unit DEV is used as the liquid treating unit U31. The developing unit DEV performs developing treatment on the substrate W. The liquid treating units U31 each include a holding rotator 161, nozzles 163, and a nozzle moving mechanism 165, which is similar to the liquid treating unit U11. The nozzles 163 supply a developing solution to the substrate W.

Moreover, as for the treating unit U32, a cooling unit CP and a post-bake unit PB are used, for example. The post-bake units PB each perform a baking treatment on the substrate W after the developing treatment. Here, the number and types of the treating units U11, U12, U21, U22, U31, and U32 are appropriately variable.

(1-6) Construction about Control of Substrate Treating System 1

Reference is made again to FIG. 1. The substrate treating system 1 includes a main controller 191 and a memory unit (not shown). The main controller 191 includes one or more processors like a central processing unit (CPU), for example. The memory unit includes, for example, at least one of a read-only memory (ROM), a random-access memory (RAM), and a hard disk. The memory unit stores computer programs and the like necessary for controlling each component of the substrate treating system 1. The main controller 191 is communicably connected to a controller 134 of the polishing treatment device 2. Moreover, the main controller 191 is communicably connected to controllers, not shown, of the coating device 3, the treating device 5, the exposure device EXP, and the developing device 7. The controllers each include one or more processors.

### (2) Operation of Substrate Treating System 1

The following describes operation of the substrate treating system 1 with reference to FIG. 1 and the like. A transport vehicle 9B of the carrier transport device 9 moves along a rail 9A. Then, the transport vehicle 9B transports the carrier C to any of four carrier platforms 11 of the polishing treatment device 2.

Reference is made to FIG. 2. The polishing treatment device 2 polishes the back face of the substrate W according to the flowchart of FIG. 8. Detailed operation of the polishing treatment device 2 is as described above. The substrate W whose back face is subjected to the polishing returns back to the carrier C placed on the carrier platform 11. Then, the transport vehicle 9B transport the carrier C from the carrier platform 11 of the polishing treatment device 2 to any of the four carrier platforms 141 of the coating device 3 (see FIG. 1).

Reference is made to FIG. 13. The indexer robot IR2 of the coating device 3 takes a substrate W from the carrier C transported to the carrier platform 141, and transports the substrate W to the substrate platform PS1. The substrate transporting robot TR2 of the treating block B4 receives the substrate W from the substrate platform PS1, and transports the substrate W to the cooling unit CP, the coating unit BARC, and the heat treating unit PAB in this order. At this time, the coating unit BARC forms an antireflection film on the front face of the substrate W. Then, the substrate transporting robot TR1 receives the substrate W from the heat treating unit PAB, and transports the substrate W to the cooling unit CP, the coating unit PR, the heat treating unit PAB, and the substrate platform SP1 in this order. At this time, the coating unit PR coats the front face of the substrate W with the resist. Specifically, the coating unit PR forms a resist film on the antireflection film.

Then, the indexer robot IR2 receives the substrate W coated with the resist from the substrate platform PS1, and returns the substrate W to the carrier C placed on the carrier platform 141. Then, the transport vehicle 9B transport the carrier C from the carrier platform 141 of the coating device 3 to any of four carrier platforms 171 of the treating device 5 (see FIG. 1).

Reference is made to FIG. 14. The indexer robot IR3 of the treating device 5 takes a substrate W from the carrier C transported to the carrier platform 171, and transports the substrate W to the substrate platform PS2. The substrate transporting robot TR3 of the treating device 5 receives the substrate W from the substrate platform PS2, and transports the substrate W to the edge exposing unit EEW, the inversion unit RV, the back face cleaning unit BSS, the inversion unit RV, and the substrate platform PS3 in this order.

Thereafter, the substrate transporting robot TR4 of the interface block B7 takes the substrate W from the substrate platform PS3, and unloads the substrate W to the exposure device EXP. Then, the exposure device EXP performs exposure treatment on the resist with which the front face of the substrate W is coated. The back face of the substrate W is polished by the polishing treatment device 2 at this time, whereby the defocus drawback can be overcome.

Then, the substrate transporting robot TR4 loads the substrate W, on which the exposure treatment, is performed by the exposure device EXP, and transports the substrate W to the substrate platform PS9. Thereafter, the substrate transporting robot TR5 of the interface block B7 takes the substrate W from the substrate platform PS9, and transports the substrate W to the post-exposure bake treatment unit PEB of the treating block B6. Thereafter, the substrate transporting robot TR3 of the treating block B6 receives the substrate W from the post-exposure bake treatment unit PEB, and transports the substrate W to the substrate platform PS2.

Then, the indexer robot IR3 receives the substrate W from the substrate platform PS2, and returns the substrate W to the carrier C placed on the carrier platform 171. Then, the transport vehicle 9B transport the carrier C from the carrier platform 171 of the treating device 5 to any of four carrier platforms 181 of the developing device 7 (see FIG. 1).

Reference is made to FIG. 15. The indexer robot IR4 of the developing device 7 takes a substrate W from the carrier C transported to the carrier platform 181, and transports the substrate W to the substrate platform PS11. The substrate transporting robot TR6 of the treating block B9 receives the substrate W from the substrate platform PS11, and transports the substrate W to the cooling unit CP, the developing unit DEV, the post-bake unit BP, and the substrate platform PS11 in this order. At this time, the developing unit DEV performs developing treatment on the substrate W. Then, the indexer robot IR4 receives the substrate W, on which the developing treatment is performed, from the substrate platform PS11, and returns the substrate W to the carrier C placed on the carrier platform 181. Then, the transport vehicle 9B transports the carrier C from the carrier platform 181 of the developing device 7 to a next destination.

According to this embodiment, the polishing treatment device 2 (holding rotator 35, polisher 96, and hot plate 45 (heating member)) and the coating device 3 are provided. The polisher 96 has a resin body in which abrasive grains are distributed. The polisher 96 polishes the back face of the substrate W in the chemo-mechanical grinding (CMG) manner by contacting against the back face of the rotating substrate W. When such polishing is performed, the substrate W is heated by the hot plate 45. When the substrate W is heated, the polishing rate can increase (see FIG. 11). This can shorten time for polishing treatment. Moreover, with the polishing treatment device 2 and the coating device 3, the front face of the substrate W is coated with the resist, and the polishing is performed to the back face of the substrate W. This achieves sufficient flatness of the substrate W coated with the resist, whereby the defocus drawback of the exposure device EXP can be overcome.

Moreover, the inspecting unit 20 for inspecting the substrate W detects a scratch formed on the back face of the substrate W before the back face of the substrate W is polished. Moreover, the inspecting unit 20 polishes the back face of the substrate W when a scratch is detected. This can scrape the detected scratch, i.e., a selected scratch.

Moreover, the inspecting unit 20 measures a depth of a scratch when the scratch is detected. The polishing unit 22 polishes the back face of the substrate W until a thickness corresponding to the depth of the scratch measured by the inspecting unit 20 is scraped off. Accordingly, the depth of the scratch is recognized, achieving a suitable amount of polishing in a thickness direction of the substrate W.

With the polishing treatment device 2, the polisher 96 polishes the back face of the substrate W in the chemo-mechanical grinding (CMG) manner by contacting against the back face of the rotating substrate W. Here, it is found that, when a film FL is formed on the back face of the substrate W, the polishing cannot be performed suitably due to the film FL. Then, the film FL formed on the back face of the substrate W is removed by etching treatment prior to polishing treatment. This can perform the polishing treatment suitably.

### SECOND EMBODIMENT

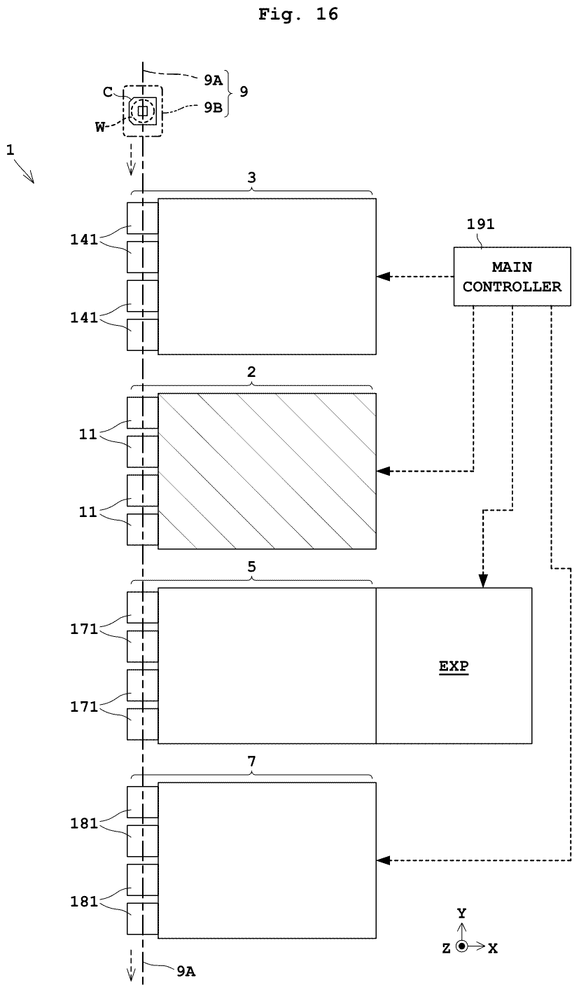

The following describes a second embodiment of the present invention with reference to the drawings. Here, the description common to that of the first embodiment is to be omitted. FIG. 16 is a plan view of a substrate treating system 1 according to the second embodiment.

In the first embodiment, a substrate W whose back face is polished by the polishing treatment device 2 is transported to the coating device 3. In this regard, in the second embodiment, a substrate W that the coating device 3 has coated with a resist is transported to the polishing treatment device 2. That is, the polishing treatment device 2 and the coating device 3 are arranged reversely.

Reference is made to FIG. 16. In a transportation path (rail 9A) of the carrier C by the transport vehicle 9B, the polishing treatment device 2 is located between the coating device 3 and the treating device 5. Accordingly, the substrate treating system 1 shown in FIG. 16 operates as under.

The coating device 3 coats a front face of a substrate W with a resist. Then, the polishing treatment device 2 polishes a back face of the substrate W. Specifically, a holding rotator 35 (FIG. 4) of a polishing unit 22 in the polishing treatment device 2 rotates the substrate W, coated with the resist, in a horizontal posture. The polishing unit 22 polishes the back face of the substrate W in a chemo-mechanical grinding manner by contacting a polisher 96, having a resin body where abrasive grains are distributed, against the back face of the rotating substrate. A hot plate 45 as a heating member heats the substrate W while the polishing is performed.

After the back face of the substrate W is polished, an exposure device EXP performs exposure treatment on the resist with which the front face of the substrate W, whose back face being polished, is coated. Then, the developing device 7 performs a developing treatment on the substrate W subjected to the exposure treatment.

This embodiment can obtain the same effect as that of the first embodiment. Specifically, the polishing treatment device 2 (holding rotator 35, polisher 96, and hot plate 45 (heating member)) and the coating device 3 are provided. The polisher 96 has a resin body in which abrasive grains are distributed. The polisher 96 polishes the back face of the substrate W in the chemo-mechanical grinding (CMG) manner by contacting against the back face of the rotating substrate W. When such polishing is performed, the substrate W is heated by the hot plate 45. When the substrate W is heated, the polishing rate can increase (see FIG. 11). This can shorten time for polishing treatment. Moreover, with the polishing treatment device 2 and the coating device 3, the front face of the substrate W is coated with the resist, and the polishing is performed to the back face of the substrate W. This achieves sufficient flatness of the substrate W coated with the resist, whereby the defocus drawback of the exposure device EXP can be overcome.

Here in this embodiment, the polishing treatment device 2 performs a back-face cleaning treatment after the back face is polished (step S06 in FIG. 8). Accordingly, the treating device 5 need not provide the back face cleaning unit BSS.

### THIRD EMBODIMENT

(3) Polishing head 201

The following describes a preferred construction of the polishing mechanism 37 (third embodiment) mentioned above with reference to FIG. 17. FIG. 17 illustrates a preferred construction of a polishing mechanism of a polishing unit. The description common to that of the first and second embodiments is to be omitted.

A polishing mechanism 37A differs from the polishing mechanism 37 described above in the following construction.

A polishing head 201 is attached to an attachment member 98. The polishing head 201 includes a polisher 96.

A shaft 100 to which the attachment member 98 is attached includes inside thereof a gas supply pipe 203 and a suction pipe 205. The gas supply pipe 203 and the suction pipe 205 are arranged in parallel in the shaft 100. The gas supply pipe 203 and the suction pipe 205 are inserted into the shaft 100. The gas supply pipe 203 and the suction pipe 205 are in communication with a rotary joint 207. The rotary joint 207 has a fixing body 209 and a rotating body 211. The fixing-side body 209 is fixed to an arm 101. The rotating-side body 211 is attached to the shaft 100. The rotary joint 207 can cause at least two types of fluids to run between the fixing-side body 209 fixed to the arm 101 and the rotating-side body 211 rotating along with the shaft 100.

The gas supply pipe 203 extending from the rotary joint 207 has a first end in communication with a gas supplying source 213. The gas supplying source 213 supplies gas. The gas is preferably an inert gas. The inert gas is, for example, nitrogen gas. The gas supply pipe 203 includes a flow rate regulating valve 215 and an on-off valve 217. The flow rate regulating valve 215 regulates a flow rate of gas that flows in the gas supply pipe 203. The on-off valve 217 permits or blocks flow of the gas in the gas supply pipe 203.

The suction pipe 205 extending from the rotary joint 207 has a first end in communication with a suction source 219. The suction source 219 sucks an interior of the suction pipe 205. The suction source 219 sucks gas. The suction source 219 is, for example, a suction pump or a utility for suction provided in a clean room. The suction pipe 205 includes an on-off valve 221. The on-off valve 221 permits or blocks flow of the gas in the suction pipe 205.

The on-off valves 217 and 221 mentioned above and the flow rate regulating valve 215 are operated by the controller 134. Here, the flow rate regulating valve 215 and the on-off valve 217 are called a control valve.

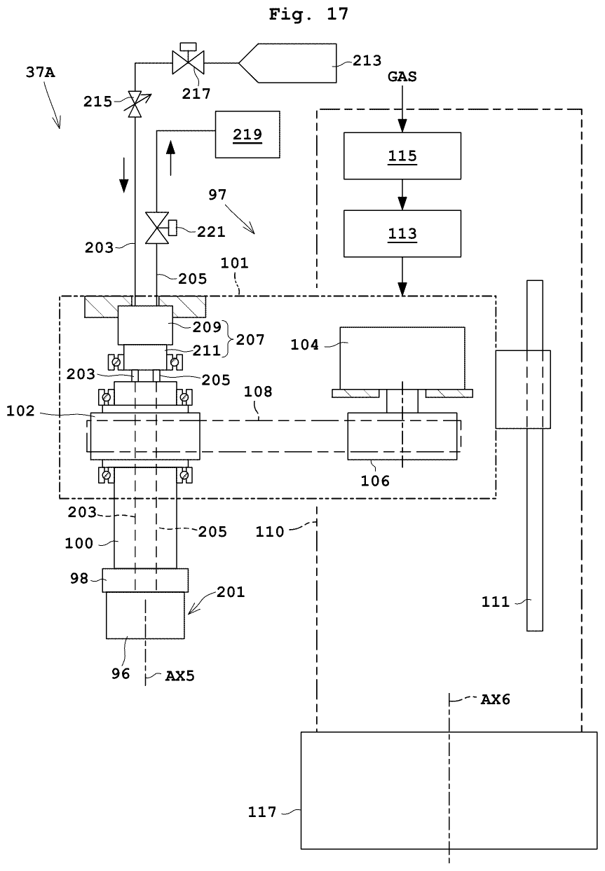

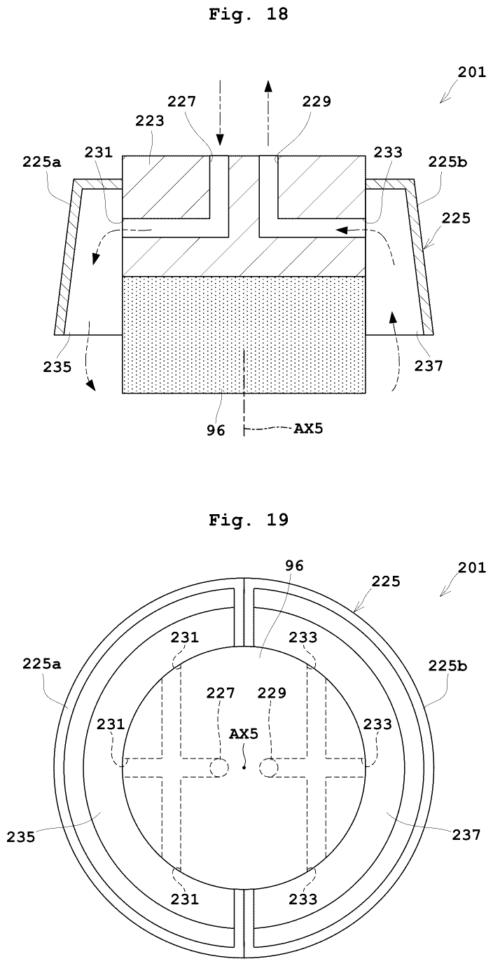

Reference is now made to FIGS. 18 and 19. FIG. 18 is a longitudinal cross-sectional view of a polishing head according to the third embodiment. FIG. 19 is a bottom view of the polishing head according to the third embodiment.

The polishing head 201 includes the polisher 96, a head body 223, and a cover 225. The polisher 96 is attached to a lower face of the head body 223. The head body 223 has a first flow path 227 and a second flow path 229 formed therein. The first flow path 227 and the second flow path 229 are not in communication with each other. The first flow path 227 and the second flow path 229 cause an upper face and an outer circumferential face of the head body 223 to communicate with each other. The first flow path 227 has three openings 231 in the outer circumferential face of the head body 223, for example. The second flow path 229 has three openings 233 in the outer circumferential face of the head body 223, for example. The first flow path 227 and the second flow path 229 are preferably formed to be axially symmetric with reference to a straight line passing the vertical axis AX5 in plan view.

The cover 225 is attached to the head body 223. The cover 225 is attached to the outer circumferential face of the head body 223. The cover 225 has a shape inclined outward from a portion extending horizontally, for example. In other words, the cover 225 has a trapezoid shape. The cover 225 has a lower end higher than a lower face of the polisher 96. This is to prevent interference between the cover 225 and the substrate W even when the polisher 96 is worn. The cover 225 includes a first cover 225a and a second cover 225b. The first cover 225a and the second cover 225b are formed to be axially symmetric with reference to the straight line passing the vertical axis AX5 in plan view.

The first cover 225a covers the opening 231 laterally. The second cover 225b covers the opening 233 laterally. A lower part of the first cover 225a forms a jet port 235. A lower part of the second cover 225b forms a suction port 237. The jet port 235 is provided along a half of the outer circumferential face of the polisher 96. The suction port 237 is provided along a half of the outer circumferential face of the polisher 96. The suction port 237 and the jet port 235 are formed to be axially symmetric with reference to the straight line passing the vertical axis AX5 in plan view.

In the polishing head 201, the first flow path 227 is in communication with a second end of the gas supply pipe 203. In the polishing head 201, the second flow path 229 is in communication with a second end of the suction pipe 205. In other words, the jet port 235 communicates with the gas supplying source 213. The suction port 237 communicates with the suction source 219.

The polishing unit 22 configured in such a manner as above polishes the substrate W as under, for example. Note that the arm 101 and the like operate as described above.

The controller 134 performs operation concerning supply and suction of gas. Specifically, the controller 134 sets in advance a predetermined supply flow rate of the flow rate regulating valve 215. The predetermined supply flow rate is preferably set within a range not exceeding a flow rate sucked from the suction pipe 205. The controller 134 opens the on-off valves 217 and 221 at a timing or a slightly earlier timing of starting the polishing treatment. Thereby, nitrogen gas is supplied to the gas supply pipe 203 at a predetermined supply flow rate, and gas is sucked from the suction pipe 205.

According to this embodiment, dust particles generated at the back face of the substrate W due to polishing by the polisher 96 rotating around the vertical axis AX5 are also pushed out toward an outer circumference side of the polisher 96 by a centrifugal force. At this side, nitrogen gas is jetted from the jet port 235. Thereby, the dust particles attached to the back face of the substrate W are removed from the back face of the substrate W. The dust particles are sucked through the suction port 237. Consequently, the dust particles are hard to remain on the back face of the substrate W, achieving enhanced removal rate of dust particles caused by the polishing.

Moreover, in this embodiment, the outer circumferential face of the polisher 96 is divided axial-symmetrically in plan view, and separated parts serve as the jet port 235 and the suction port 237. This achieves a suitably maintained balance between supply and suction of the nitrogen gas at the outer circumferential face of the polisher 96. As a result, the dust particles can be removed suitably.

Moreover, with this embodiment, the flow rate of nitrogen gas from the jet port 235 is set so as not to exceed the suction flow rate. Accordingly, the dust particles are not sucked from the suction port 237 due to jetting of the nitrogen gas from the jet port 235, leading to preventing scattering around.

Moreover, it is preferred that the controller 134 operates the flow rate regulating valve 215 to change a flow rate of nitrogen gas temporally. The flow rate in this case includes a flow rate of zero where no nitrogen gas is supplied. Thereby, a difference occurs in the flow rate of nitrogen gas jetted from the jet port 235. In other words, the nitrogen gas is supplied not constantly but discontinuously or intermittently. Moreover, the controller 134 may operate opening and closing of the on-off valve 217 while the flow rate is made constant without operating the flow rate regulating valve 215. Thereby, the jet port 235 jets the nitrogen gas discontinuously or intermittently.

When the nitrogen gas is jetted continuously, the dust particles are pressed against the back face of the substrate W, leading to an impossibility of smooth suction or removal. Here, the controller 134 operates the flow rate regulating valve 215 or the on-off valve 217 to make discontinuous jetting of nitrogen gas from the polishing head 201. When the nitrogen gas is jetted discontinuously and intermittently, a pressing force by the nitrogen gas is weakened temporarily. As a result, the dust particles are easily removable.

### FOURTH EMBODIMENT

The following describes a fourth embodiment of the present invention with reference to the drawings. The constructions except a polishing head 201A are same as those described in the embodiments above.

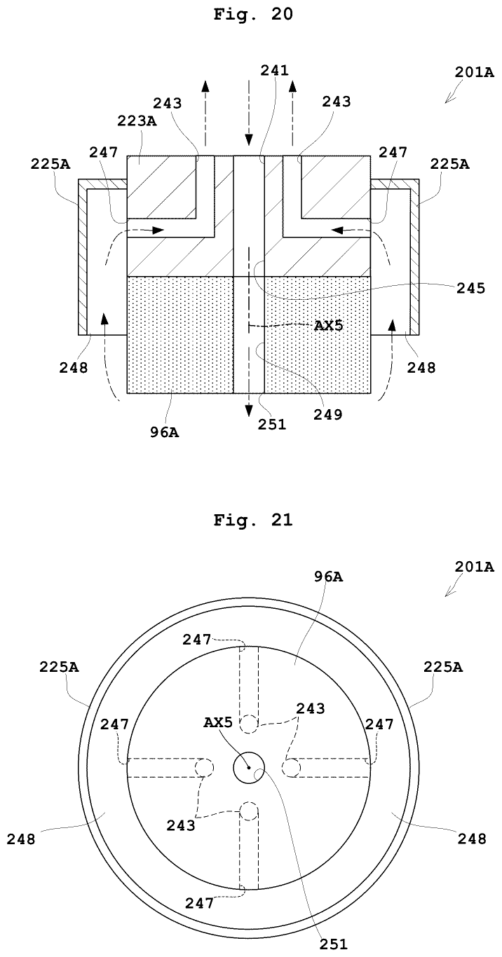

Reference is now made to FIGS. 20 and 21. FIG. 20 is a longitudinal cross-sectional view of a polishing head according to the fourth embodiment. FIG. 21 is a bottom view of the polishing head according to the fourth embodiment.

The polishing head 201A includes a polisher 96A, a head body 223A, and a cover 225A. The polisher 96A is attached to a lower face of the head body 223A. The head body 223A has a first flow path 241 and a second flow path 243 formed therein.

The first flow path 241 and the second flow path 243 are not in communication with each other. The first flow path 241 has an opening 245 in a lower face of the head body 223A. The first flow path 241 substantially conforms to the vertical axis AX5. The second flow path 243 cause an upper face and an outer circumferential face of the head body 223A to communicate with each other. The second flow path 243 has four openings 247 in the outer circumferential face of the head body 223A, for example. The second flow path 243 also communicates with four openings in the upper face of the head body 223A, for example. The second flow path 243 preferably has the openings 247 whose positional relationship are equal to one another in angle in plan view. This yields uniform suction.

The cover 225A is attached to the head body 223A. The cover 225A is attached to an outer circumferential face of the head body 223A. The cover 225A has a shape suspended downward from a portion directing horizontally, for example. The cover 225A has a lower end higher than a lower face of the polisher 96A. A lower part of the cover 225A forms a suction port 248.

A through hole 249 is formed in the center of the polisher 96A. The polisher 96A is annular in plan view. The through hole 249 substantially overlaps the vertical axis AX5 in plan view. The through hole 249 overlaps the first flow path 241 in plan view. The through hole 249 communicates with the first flow path 241. An opening of the through hole 249 communicating with the lower face of the polisher 96A corresponds to a jet port 251.

In the polishing head 201A, the first flow path 241 is in communication with a second end of a gas supply pipe 203. In the polishing head 201A, the second flow path 243 is in communication with a second end of a suction pipe 205. In other words, the jet port 251 communicates with a gas supplying source 213. The suction port 248 communicates with a suction source 219.

According to this embodiment, nitrogen gas jetted from the center of the polisher 96A runs over the back face of the substrate W toward the outer periphery of the polisher 96A. This can achieve efficient suction of the nitrogen gas, containing the dust particles, through the suction port 248.

### FIFTH EMBODIMENT

The following describes a fifth embodiment of the present invention with reference to the drawings. The constructions except a polishing head 201B are same as those described in the embodiments above.

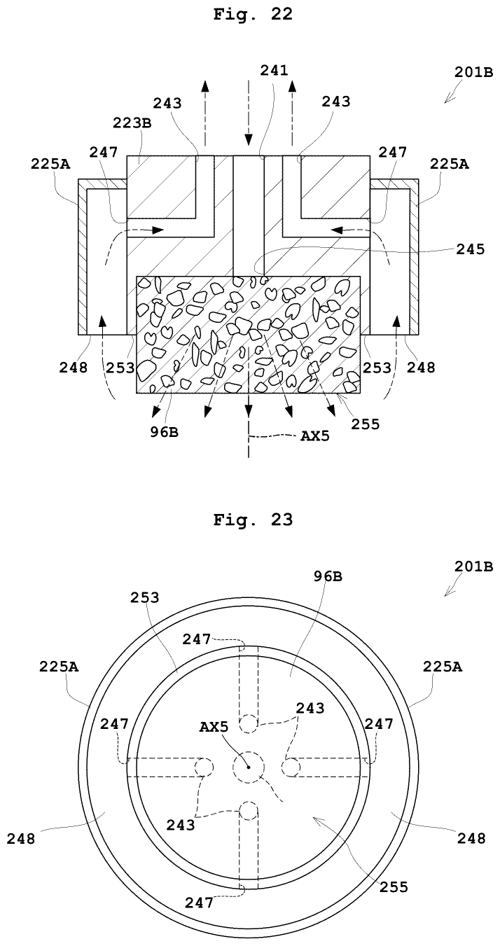

Reference is now made to FIGS. 22 and 23. FIG. 22 is a longitudinal cross-sectional view of a polishing head according to the fifth embodiment. FIG. 23 is a bottom view of the polishing head according to the fifth embodiment.

The polishing head 201B includes a polisher 96B, a head body 223B, and a cover 225A. The polisher 96B is attached to a lower face of the head body 223B. The head body 223B has a first flow path 241 and a second flow path 243 formed therein. The first flow path 241 and the second flow path 243 are same as those described in the fourth embodiment. An edge 253 is formed in the head body 223B. The edge 253 is formed by an edge portion of a lower face of the head body 223B protruding downward. The polishing member 96B is attached to the edge 253.

The polisher 96B is formed by a porous member. Many fine holes are formed in the polisher 96B. Many fine holes of the polisher 96B are in communication with one another. Nitrogen gas supplied from the first flow path 241 is jetted from the lower face to the back face of the substrate W through many fine holes of the polisher 96B. In other words, the lower face of the polisher 96B constitutes a jet port 255.

The cover 225A is configured in the same manner as that in the fourth embodiment described above, and has a suction port 248 formed in its lower part.

According to this embodiment, nitrogen gas is supplied to the polisher 96B made of the porous member, and the nitrogen gas can be jetted to dust particles from the jet port 255 corresponding to substantially the entire of the lower face of the polisher 96B. As a result, dust particles can be pushed out efficiently to an outer periphery.

### SIXTH EMBODIMENT

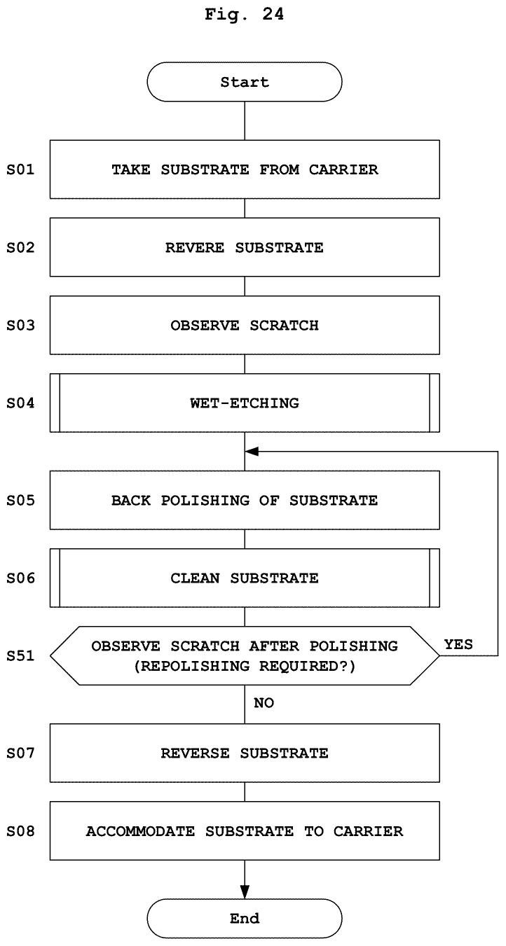

A sixth embodiment of the present invention will now be described with reference to the drawings. Here, the description common to that of the first to fifth embodiments is to be omitted. FIG. 24 is a flow chart illustrating operation of a polishing treatment device according to the sixth embodiment.

In the first embodiment, scratch observation is not performed after a back face of a substrate W is polished (step S05). In this regard, scratch observation is performed after a back face of a substrate W is polished (step S51 in FIG. 24) in the sixth embodiment.

Here, operation substantially same as that in the steps S01 to S08 shown in FIG. 8 is performed in the steps S01 to S08 shown in FIG. 24, respectively. After a cleaning step of a substrate W (step S06), a substrate transporting robot CR takes the substrate W from a polishing unit 22, and transports the substrate W to a stage 121 of one of two inspecting units 20.

[Step S51] Observing Scratch after Polishing

The inspecting unit 20 especially detects the scratch formed on the back face of the substrate W again. That is, similar to the operation of step S03, the inspecting unit 20 acquires an observed image by a camera 124 and a lighting portion 125. An inspection controller 130 extracts a scratch to be polished by performing image processing to the acquired observed image. When a scratch to be polished is not extracted, a controller 134 determines that repolishing is unnecessary, and the procedure proceeds to the step S07.

In contrast to this, when a scratch to be polished is extracted, the controller 134 determines that repolishing is necessary. Then, the inspecting unit 20 measures a depth of the scratch to be polished. That is, a laser microscope 127 captures a three-dimensional image containing the scratch to be polished. The inspection controller 130 measures a depth of the scratch to be polished (value DP3 in FIG. 9(b)) by performing image processing to the obtained three-dimensional image.

Thereafter, the substrate transporting robot CR transports the substrate W from the stage 121 of the inspecting unit 20 to a holding rotator 35 of the polishing unit 22. After the transportation, the substrate W is held by the holding rotator 35, and gas is ejected from a gas ejection port 47. Then, a substrate thickness measuring device 39 is moved above the substrate W, and measures a thickness of the substrate W (value TK3 in FIG. 9(b)). The procedure returns to the step S05.

In the step S05, the polishing unit 22 again polishes the back face of the substrate W when the inspecting unit 20 extracts a scratch to be polished. Polishing is performed until the thickness (value DP3) corresponding to the depth of the scratch is scraped off. In other words, polishing is performed until the thickness of the substrate W is brought into a value TK2 (=TK3−DP3) shown in FIG. 9(b).

According to this embodiment, since polishing is performed until a scratch to be polished that needs polishing is eliminated, a new damage on a substrate stage of an exposure device EXP, for example, caused by the edge of the scratch may be prevented.

Moreover, when a scratch to be polished is present in this embodiment, a wet-etching step (step S04) is not performed before the back face is polished again. In this regard, the wet-etching may be performed, as necessary.

### SEVENTH EMBODIMENT

A seventh embodiment of the present invention will now be described with reference to the drawings. Here, the description common to that of the first to sixth embodiments is to be omitted.

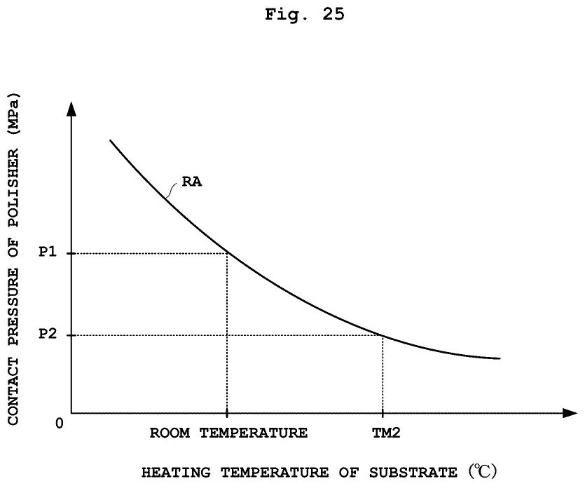

FIG. 25 illustrates a relationship between a heating temperature of a substrate W and a contact pressure (pushing pressure) of a polisher 96. FIG. 25 is a view where the polishing rate is made constant. In FIG. 25, it is assumed that a given polishing rate RA is obtained when the substrate W has the temperature of room temperature (e.g., 25° C.) and given contact pressure P1. When the substrate W is heated, the polishing rate increases. Accordingly, a contact pressure P2 lower than the contact pressure P1 is obtainable when the temperature is made higher than room temperature (e.g., temperature TM2) while the polishing rate RA is maintained. That is, if the polishing rate RA is constant, the contact pressure can be lowered by raising the temperature of the substrate W.

With this embodiment, a polishing unit 22 can adjust the polishing rate by controlling the contact pressure of the polisher 96 against the substrate W in addition to the heating temperature of the substrate W. For example, raising the heating temperature of the substrate W while keeping the polishing rate allows decreased contact pressure of the polisher 96 against the substrate W. This can suppress load of the substrate W caused by the contact pressure. That is, excess pushing against the substrate W can be prevented.

Here, adjustment of the polishing rate is not limitedly performed from a relationship between the heating temperature of the substrate W and the contact pressure of the polisher 96. That is, adjustment of the polishing rate may be performed with use of a relationship between the heating temperature of the substrate W and a moving speed of the polisher 96. Moreover, adjustment of the polishing rate may be performed with use of a relationship between the heating temperature of the substrate W and a moving speed of the polisher 96 around a vertical axis AX6 (swinging speed). Adjustment of the polishing rate may be performed with use of a relationship between the heating temperature of the substrate W and a rotation speed of the polisher 96 around a vertical axis AX5. Adjustment of the polishing rate may be performed with use of a relationship between the heating temperature of the substrate W and a rotation speed of the substrate W.

That is, the polishing unit 22 may adjust the polishing rate by controlling at least one selected from the contact pressure of the polisher 96 against the substrate W, the moving speed of the polisher 96, the rotation speed of the polisher 96, and the rotation speed of the substrate W in addition to the heating temperature of the substrate W.

### EIGHTH EMBODIMENT

The following describes an eighth embodiment of the present invention with reference to drawings. Here, the description common to those of the first to seventh embodiments is to be omitted.

In FIG. 2, the treating unit U1 corresponds to the inspecting unit 20 and each of the treating units U2 to U4 corresponds to the polishing unit 22 in the first embodiment. In the eighth embodiment, each of treating units U2 and U3 may correspond to a polishing unit 341, and the treating unit U4 may correspond to a liquid treating unit 343. Here, a treating unit U1 corresponds to the inspecting unit 20.

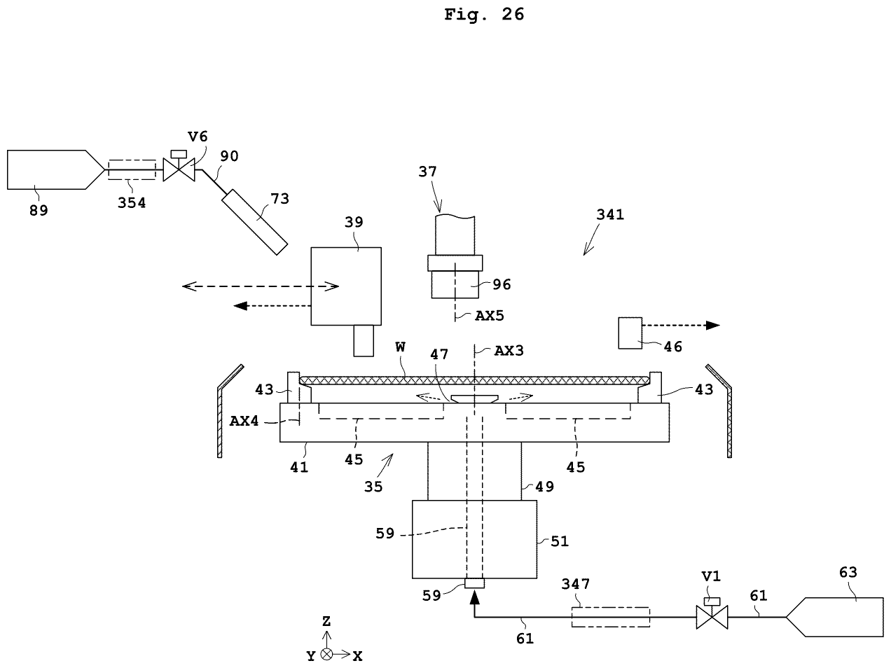

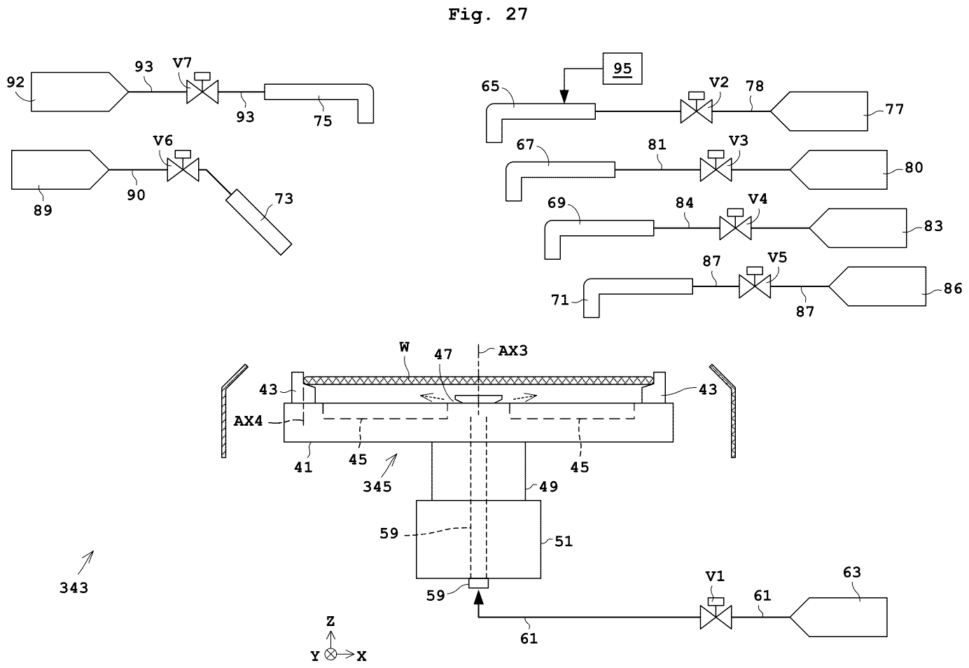

That is, the polishing treatment device 2 in the eighth embodiment includes a two-layered inspecting unit 20, two-layered two polishing units 341, and a two-layered liquid treating unit 343. In other words, the polishing treatment device 2 includes eight treating units U1 to U4. FIG. 26 illustrates the polishing unit 341 according to the eighth embodiment. FIG. 27 illustrates the liquid treating unit 343 according to the eighth embodiment.

The polishing unit 341 and the liquid treating unit 343 are formed by dividing the polishing unit 22 in FIG. 4 into two, for example. Here, the liquid treating unit 343 includes a second holding rotator 345 that is configured in the same manner as the holding rotator 35. Moreover, the polishing unit 341 may include a rinse liquid nozzle 73, a rinse liquid supplying source 89, and a rinse liquid pipe 90.

The polishing treatment device 2 operates in accordance with the flow chart shown in FIG. 8 or FIG. 24. However, the substrate W is transported between the polishing unit 341 and the liquid treating unit 343, for example. In the steps S03 to S06 in FIG. 8, for example, the substrate W is transported by a substrate transporting robot CR to the inspecting unit 20, the liquid treating unit 343 (wet-etching step), the polishing unit 341, and the liquid treating unit 343 (cleaning step of the substrate W) in this order.

This embodiment produces the same effect as that of the first embodiment. Moreover, the polishing unit 341 and the liquid treating unit 343 can each be made compact since they are formed by dividing the polishing unit 22 in FIG. 4 into two, for example.

Here, the polishing unit 341 may be provided with a construction concerning the wet-etching step (step S04) in the liquid treating unit 343. Moreover, the polishing unit 341 may be provided with a construction concerning the cleaning step (step S06) of the substrate W in the liquid treating unit 343. Moreover, in the eighth embodiment, the polishing unit 341 does not include heaters 347, 354 (see FIG. 26) mentioned later.

The present invention is not limited to the foregoing examples, but may be modified as follows.

(1) In the embodiments described above, suction is performed from the suction ports 237 and 248 with large openings provided in the covers 225 and 225A, respectively. However, the present invention is not limited to this configuration. For example, such a pipe configuration may be adopted that a first end of the pipe communicates with the openings 233 and 247 of the head body 223 (223A, 223B) and a second end of the pipe faces a polishing face.

(2) In each of the embodiments described above, nitrogen gas is jetted from the jet port. However, gas is not limited to nitrogen gas in the present invention. For example, argon gas may be used as the gas.

(3) In each of the embodiments described above, the gas supply pipe 203 and the suction pipe 205 are arranged in parallel. However, the present invention is not limited to this construction. For example, such a construction may be adopted that a jacketed pipe is inserted into the shaft 100 for gas supply and suction.

(4) In each of the embodiments described above, the controller 134 operates the flow rate regulating valve 215 to change a flow rate of the nitrogen gas temporally. However, such operation is not essential in the present invention. That is, the flow rate of the nitrogen gas may be kept constant during the polishing treatment.

(5) In each of the embodiments described above, the polishing heads 201, 201A, and 201B are removably attached to the attachment member 98. However, such is adoptable that the polishing heads 201, 201A, and 201B are semi-fixed to the attachment member 98 and the polishers 96, 96A, 96B are only attachable and detachable, and thus easily replaceable.

(6) In each of the embodiments described above, the polishing unit 22 includes the hot plate 45 as the heating member. Instead of the hot plate 45, the polishing unit 22 may be configured such that the gas ejection port 47 ejects heated gas. Heated gas from the gas ejection port 47 can heat the substrate. In this case, the polishing unit 22 may include a heater 347 (see FIGS. 4 and 26) for heating gas, passing through the gas pipe 61, from outside of the gas pipe 61, for example. In this case, the polishing unit 22 does not necessarily include the hot plate 45. Moreover, the substrate W may be heated by both the hot plate 45 and the heated gas ejected from the gas ejection port 47. The gas ejection port 47 corresponds to the heating member in the present invention.

(7) In each of the embodiments and the modifications described above, the polishing unit 22 includes the hot plate 45 as the heating member. In this regard, as shown in FIGS. 28(a) and 28(b), the polishing unit 22 may include a heater 349 (352), instead of the hot plate 45, for heating the polisher 96. Alternatively, the polishing unit 22 may include the hot plate 45 and the heater 349 (352). In FIG. 28(a), an attachment member 98 is configured like a vessel whose lower face is recessed. The heater 349 in a ring shape is provided on a hollow tubular portion 350 of the attachment member 98 surrounding the polisher 96 (vertical axis AX5). The heater 349 heats the polisher 96. When the polisher 96 is heated, the substrate W can be heated via the polisher 96. Moreover, an interface between the polisher 96 and the back face of the substrate W can be heated effectively.

Moreover, as shown in FIG. 28(b), the heater 352 may be embedded in the attachment member 98 and arranged between the shaft 100 and the polisher 96. Here, the heaters 349 and 352 may each perform heating with an electric heater such as a nichrome wire, for example. Moreover, the heaters 349 and 352 may each include a pipe and perform heating by supplying heated gas or a heated liquid through the pipe. The heaters 349 and 352 each correspond to the heating member in the present invention.

(8) In each of the embodiments (except the third to fifth embodiments) and the modifications described above, the back face of the substrate W is polished with the polisher 96 in the dry chemo-mechanical grinding manner. In this regard, the polisher 96 may polish the back face of the substrate W in the chemo-mechanical grinding manner by supplying a liquid over the back face of the substrate W. For example, the rinse liquid nozzle 73 (FIGS. 4 and 26) may supply heated pure water (e.g., DIW) over the back face of the substrate W and in the vicinity of the polisher 96. Heated pure water can heat the substrate W. Moreover, heated pure water can wash off the polishing scraps from the back face of the substrate W. For example, the polishing unit 22 (341) may include a heater 354 for heating pure water, passing through the rinse liquid pipe 90, from outside of the rinse liquid pipe 90. Moreover, the substrate W may be heated by the heated pure water from the rinse liquid nozzle 73 without being heated by the hot plate 45. In this case, the polishing unit 22 does not necessarily include the hot plate 45. Here, the rinse liquid nozzle 73 corresponds to the heating member in the present invention.

Moreover, the substrate W may be heated by at least one selected from the hot plate 45, the gas ejection port 47 that ejects heated gas, the heater 349 (or heater 352) for heating the polisher 96, and the rinse liquid nozzle 73 for supplying the heated pure water to the back face of the substrate W.

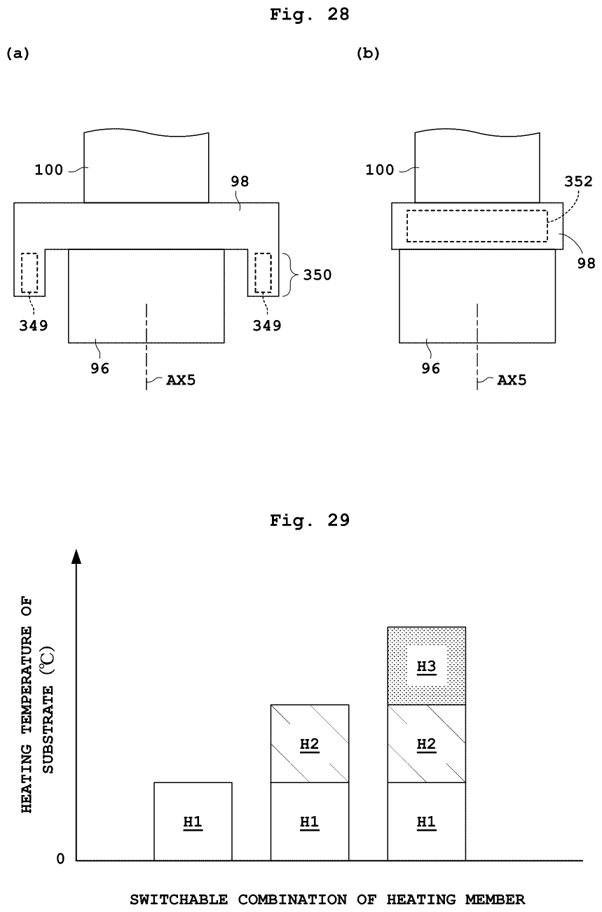

Moreover, the polishing unit 22 may include these heating members, and may combine the heating members for controlling the heating temperature of the substrate W. For example, it is assumed that heating is performed only by the hot plate 45 (numeral H1 in FIG. 29). When more heating is required, the substrate W may be heated by the gas ejection port 47, in addition to the hot plate 45, that ejects heated gas (numeral H1 and numeral H2 in FIG. 29). Moreover, when further heating is required, the substrate W may be heated by the heater 349 (or heater 352), in addition to the hot plate 45 and the gas ejection port 47, that heats the polisher 96 (numeral H1, numeral H2, and numeral H3 in FIG. 29). When heating needs to be suppressed from this state, the substrate W may be heated only by the hot plate 45 (numeral H1).

(9) In each of the embodiments and the modifications described above, the substrate thickness measuring device 39 measures the thickness of the substrate W prior to the wet-etching step (step S04). In this regard, the substrate thickness measuring device 39 may measure the thickness of the substrate W between the step S04 and the back polishing step (step S05) of the substrate W. In this case, the scratch observing step (step S03) may be shifted between the steps S04 and S05.

(10) In each of the embodiments and modifications described above, the contact pressure of the polisher 96 against the substrate W may be detected by a load cell, for example. Moreover, the moving speed of the polisher 96 may be detected by a rotary encoder that detects an angle of the polisher 96 around the vertical axis AX6. Moreover, the rotation speed of the polisher 96 may be detected by a rotary encoder that detects an angle of the polisher 96 around the vertical axis AX5. Moreover, the rotation speed of the substrate W may be detected by a rotary encoder that detects an angle of the substrate W around the rotary axis AX3. The controller 134 may control each component based on these detected results.

(11) In each of the embodiments and the modifications mentioned above, the holding rotator 35 holds the substrate W, whose back face is directed upward, in a horizontal posture. Moreover, the spin base 41 of the holding rotator 35 is arranged below the substrate W. In this regard, the holding rotator 35 may be arranged upside down. That is, the spin base 41 of the holding rotator 35 is arranged above the substrate W. Moreover, the holding rotator 35 holds the substrate W, whose back face is directed downward, in a horizontal posture. In this case, the polisher 96 is brought into contact against the substrate W whose back face is directed downward from a side below the substrate W.

(12) In each of the embodiments and the modifications described above, the steps S21 to S26 are performed as the wet-etching step (FIG. 10). Among the six steps S21 to S26, only the steps S21 to S23 may be performed. Moreover, among the six steps S21 to S26, only the steps S24 to S26 may be performed.

(13) In each of the embodiments and the modifications described above, the steps S31 to S36 are performed as the cleaning step of the substrate W (FIG. 12). Among the six steps S31 to S36, only the steps S31 to S33 may be performed. Moreover, among the six steps S31 to S36, only the steps S34 to S36 may be performed.

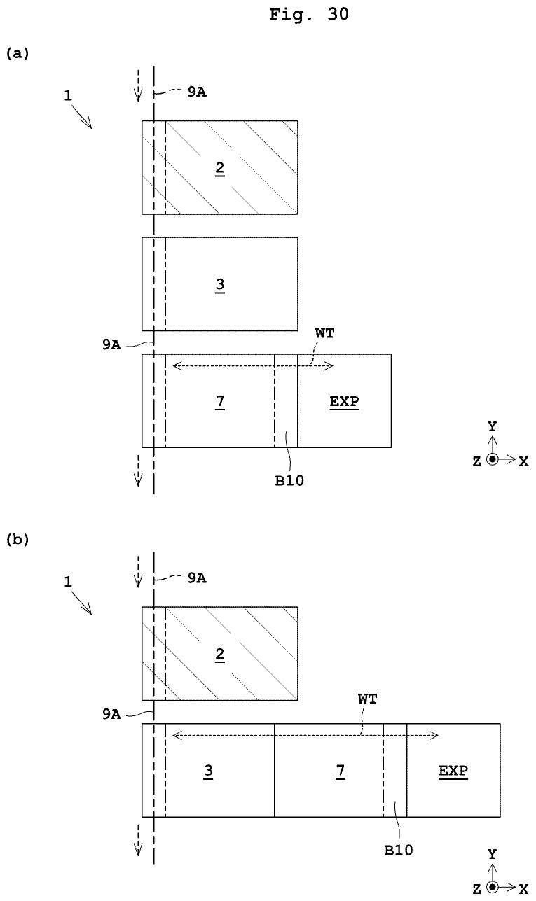

(14) In the each of embodiments and the modifications described above, the coating device 3, the developing device 7, and the exposure device EXP are separated (FIG. 1). In this regard, the developing device 7 may be connected to the exposure device EXP as shown in FIG. 30(a), for example. In this case, the developing device 7 includes an interface block B10 like the treating device 5 shown in FIG. 14. In this case, the treating units U21 and U22 of the treating device 5 are arranged in at least either the treating block B9 or interface block B10 of the developing device 7. Here, processing by the polishing treatment device 2 and processing by the coating device 3 may be reversed in FIG. 30(a). Moreover, as shown in FIG. 30(b), the coating device 3, the developing device 7, and the exposure device EXP may be integrated. Here, as shown by a numeral WT in FIGS. 30(a) and 30(b), a substrate W is transported between the coating device 3 and the exposure device EXP, for example.

Moreover, the exposure device EXP includes the light source for emitting the EUV rays. The light source may emit rays having a wavelength different from that of the EUV rays (e.g., ArF ray (193 nm) and KrF ray (248 nm)). In this case, the projection optical system may include a plurality of lenses instead of the multilayer mirrors.

### REFERENCE SIGNS LIST

1 . . . substrate treating system
2 . . . polishing treatment device
3 . . . coating device
EXP . . . exposure device
20 . . . inspecting unit
22, 341 . . . polishing unit
35 . . . holding rotator
41 . . . spin base
43 . . . holding pin
45 . . . hot plate
47 . . . gas ejection port
73 . . . rinse liquid nozzle
96, 96A, 96B . . . polisher
130 . . . inspection controller
134 . . . controller
191 . . . main controller
201, 201A, 201B . . . polishing head
235, 251, 255 . . . jet port
237, 248 . . . suction port
345 . . . second holding rotator
347, 349, 352, 354 . . . heater
SH1 . . . scratch
RA . . . polishing rate

1. A substrate treating method, comprising:
a rotating step of rotating a substrate in a horizontal posture by a holding rotator;
a polishing step of performing polishing to a back face of the substrate in a chemo-mechanical grinding manner by contacting a polisher against the back face of the rotating substrate, the polisher having a resin body where abrasive grains are distributed;
a heating step of heating the substrate while the polishing is performed;
a resist coating step of coating a front face of the substrate, whose back face is subject to the polishing, with a resist; and
an exposing step of exposing the resist with which the front face of the substrate is coated.

2. A substrate treating method, comprising:
a resist coating step of coating a front face of a substrate with a resist;
a rotating step of rotating the substrate coated with the resist in a horizontal posture by a holding rotator;
a polishing step of performing polishing to a back face of the substrate in a chemo-mechanical grinding manner by contacting a polisher against the back face of the rotating substrate, the polisher having a resin body where abrasive grains are distributed;
a heating step of heating the substrate while the polishing is performed; and
an exposing step of exposing the resist with which the front face of the substrate, whose back face is subject to the polishing, is coated.

3. The substrate treating method according to claim 1, further comprising:
a controlling step of adjusting a polishing rate by controlling a heating temperature of the substrate in the heating step.

4. The substrate treating method according to claim 3, wherein
in the controlling step, the polishing rate is adjusted by controlling at least one selected from a contact pressure of the polisher against the substrate, a moving speed of the polisher, a rotation speed of the polisher, and a rotation speed of the substrate.

5. The substrate treating method according to claim 1, wherein
the holding rotator includes:
a spin base that is rotatable around a rotary axis extending in an up-down direction,
three or more holding pins that are provided on a top face of the spin base so as to surround the rotary axis in a ring shape and configured to hold the substrate by sandwiching a side face of the substrate so that the substrate is held apart from the top face of the spin base, and
a first heater provided on the top face of the spin base, and
the first heater heats the substrate in the heating step.

6. The substrate treating method according to claim 1, wherein
the holding rotator includes:
a spin base that is rotatable around a rotary axis extending in an up-down direction,
three or more holding pins that are provided on a top face of the spin base so as to surround the rotary axis in a ring shape and configured to hold the substrate by sandwiching a side face of the substrate so that the substrate is held apart from the top face of the spin base, and
a gas ejection port that is opened in the top face of the spin base and provided in a center portion of the spin base, and
in the heating step, the gas ejection port heats the substrate by ejecting heated gas in such a manner that the gas flows in a gap between the substrate and the spin base from a portion adjacent to the center of the substrate to an outer periphery edge of the substrate.

7. The substrate treating method according to claim 1, wherein
a second heater heats the polisher, thereby heating the substrate via the polisher in the heating step.

8. The substrate treating method according to claim 1, wherein
a heated water supply nozzle supplies heated water to the back face of the substrate, held by the holding rotator, thereby heating the substrate in the heating step.

9. The substrate treating method according to claim 1, further comprising:
a dust particle suction step of jetting gas to dust particles, generated through the polishing by the polisher, from a jet port of the polishing head provided with the polisher and sucking the dust particles from a suction port of the polishing head.

10. The substrate treating method according to claim 1, further comprising:
an etching step of supplying an etching solution to the back face of the rotating substrate to remove a film formed on the back face of the substrate prior to the polishing step.

11. The substrate treating method according to claim 1, further comprising:
an inspecting step of detecting a scratch formed on a back face of the substrate by an inspecting unit prior to the etching step, wherein
the polishing step is performed when the inspecting unit detects the scratch.

12. The substrate treating method according to claim 11, wherein
in the inspecting step, the inspecting unit detects the scratch formed on the back face of the substrate and determines a depth of the scratch when the scratch is detected,
the polishing step is performed when the inspecting unit detects the scratch, and
in the polishing step, the back face of the substrate is polished until a thickness corresponding to the depth of the scratch determined by the inspecting unit is scraped off.

13. A substrate treating system, comprising:
a coating device configured to coat a front face of a substrate with a resist;
a polishing treatment device configured to polish a back face of the substrate; and
an exposure device configured to expose the resist,
the polishing treatment device including:
a holding rotator configured to rotate the substrate in a horizontal posture,
a heating member configured to heat the substrate, and
a polisher having a resin body where abrasive grains are distributed and configured to polish the back face of the substrate in a chemo-mechanical grinding manner by contacting against the back face of the substrate rotating while being heated.
